(19) United States
(12) Patent Application Publication
(10) Pub. No.: US 2007/0290604 A1
(43) Pub. Date: Dec. 20, 2007

(54) ORGANIC ELECTROLUMINESCENT DEVICE AND METHOD OF PRODUCING THE SAME

(75) Inventors: Kei SAKANOUE, Fukuoka (JP); Takafumi HAMANO, Fukuoka (JP); Shinya YAMAMOTO, Fukuoka (JP); Naoto MATSUO, Fukuoka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/762,418

(22) Filed: Jun. 13, 2007

(30) Foreign Application Priority Data
Jun. 16, 2006 (JP) 2006-167580
Aug. 1, 2006 (JP) 2006-209823
Aug. 2, 2006 (JP) 2006-210895
Aug. 4, 2006 (JP) 2006-213495

(51) Int. Cl. H05B 33/00; H01L 51/50; H01L 51/56

(52) U.S. Cl. 313/503; 313/504; 445/25; 445/24

(57) ABSTRACT

An organic electroluminescent device that can be driven over a wide brightness range from low brightness used in display applications to high brightness used in light sources, can be stably operated over a wide brightness range, is less in fluctuation between pixels, is high in the emission efficiency, is excellent in the life characteristics and has a plurality of light emitting portions is provided. An organic electroluminescent device includes a plurality of light emitting portions on a glass substrate, the light emitting portion including a pair of electrodes (anode, cathode), a light emitting layer interposed between the electrodes and a transition metal oxide layer disposed between at least one of the electrodes and the light emitting layer, the transition metal oxide layer being formed over the plurality of light emitting portions.

### BACKGROUND OF THE INVENTION

1. Field of the Invention

The invention relates to an organic electroluminescent device and a method of producing the same, in particular, a device that uses an organic electroluminescent element that is an electroluminescent element that can be used in a display or a display element of a portable telephone and various light sources and driven over a wide brightness range from low brightness to high brightness for light source applications.

2. Description of the Related Art

An organic electroluminescent element is a light emitting device that makes use of an electroluminescent phenomenon of a solid luminescent material and is partially put into practical use as a small size display.

When a polymer film is formed as a light-emitting layer by use of a coating method, as a charge injection layer that injects charges in a light emitting layer, a PEDOT: PSS (a mixture of polythiophene and polystyrene sulfonic acid: hereinafter, referred to as PEDOT) thin film is formed by means of a spin coat method. In a polymer organic electroluminescent element, by means of an inkjet or coating method, for every one pixel, a PEDOT and a light emitting layer are formed, resulting in causing pixel dispersion.

In this connection, in order to arrange a charge injection layer and a light emitting layer with high accuracy, various configurations have been proposed (for instance, patent literature 1).

Furthermore, similarly, in order to inhibit positional displacement from occurring, a structure where a light emitting layer is formed so as to overlap with a region that separates between pixels, and a boundary portion generated between adjacent light emitting layers and a boundary portion of charge injection layers such as an electron transport layer and a hole transport layer, which are constituted of an organic layer, are formed so as to coincide is proposed as well (for instance, patent literature 2).

In the structures of the patent literatures 1 and 2, in all, on a region by which pixels are separated (pixel restricting layer), a light emitting layer and a charge injection layer are disposed, and on a top layer thereof an electrode is formed by use of a vacuum deposition method.

In the deposition method, since a deposition speed is slow, it takes a long time to form a film. Furthermore, in some cases, it is difficult to form a transparent electrode having a desired composition ratio. Accordingly, in order to form an ITO (indium tin oxide) layer as an electrode film with good controllability, a sputtering method is desirably used. However, when the sputtering method is used to form, there is a problem in that an organic layer such as a light emitting layer or a carrier transport layer is sputter damaged and the characteristics tend to be deteriorated.

In this connection, as a method of avoiding such the damage being inflicted on a light emitting layer, an electroluminescent element where a top electrode is formed of a first conductive layer formed by use of a deposition method and a second conductive layer formed by use of a sputtering method, and a buffer layer is disposed therebetween to inhibit the sputter damage from being inflicted (patent literature 3) is proposed as well. However, since the first conductive layer is formed of metal, the visible light is fundamentally inhibited from transmitting. Accordingly, a film thickness has to be reduced to secure the transparency. However, the light transmission loss cannot be avoided, and, when there is irregularity in the film thickness, the transmittance is caused to fluctuate, resulting in difficulty of securing the uniformity.

In all of the patent literatures 1 through 3, organic electroluminescent display devices having a plurality of pixels are shown. However, all these have a charge injection layer made of a low molecular organic material.

On the other hand, though a single element, an organic electroluminescent element that uses, in an organic electroluminescent element that uses a low molecular layer such as Alq as a light emitting layer, in order to improve the charge injection characteristics, as a anode, a thin film of a metal oxide such as molybdenum oxide larger in the work function than tin indium oxide (ITO) is used is proposed as well (patent literature 4).

It is said that, according to the configuration, since, by use of a thin film of a metal oxide having the work function larger than that of ITO that is an existing anode material, an energy barrier with a hole transport layer or a light emitting layer can be reduced; accordingly, an organic thin film light emitting element that can lower the driving voltage and maintain the luminescence performance over a long time and is excellent in the endurance can be provided.

Furthermore, there is proposed as well a light emitting device in which, in order to make an electrode on a bottom layer side flat, a first insulating layer made of an organic resin having an opening in a portion that becomes a light emitting region is formed, and a top layer thereof is covered with thin second insulating layer made of a silicon oxide layer, a silicon nitride layer or a silicon oxynitride layer to form a light emitting layer (patent literature 5).

In the configuration, as a flattening film, a first insulating layer is used, in a light emitting region, a second insulating layer is interposed between a light emitting layer and a first electrode, and the second insulating layer is formed into a thin film of 1 to 10 nm so as to possess the tunnel effect.

Patent literature 1: JP-A No. 2003-257665

Patent literature 2: JP-A No. 2004-119304

Patent literature 3: JP-A No. 2005-63928

Patent literature 4: JP-A No. 09-63771

Patent literature 5: JP-A No. 2002-280186

However, even according to the patent literature 3, when the first conductive layer is patterned, an organic layer that is a base is exposed to an etchant such as gas plasma; accordingly, the problem is not fundamentally resolved. Furthermore, in the organic electroluminescent element as well, a light emitting layer or a charge injection layer rides on a pixel restricting layer (flattened insulating layer); accordingly, the flatness is poor and, when an upper electrode is patterned, there is a problem in that sufficient patterning accuracy cannot be obtained.

Still furthermore, owing to a step of the flattened insulating layer, in a light emitting layer, a portion having a thin film thickness is generated, resulting in causing deterioration of the characteristics in some cases.

In the light emitting device of patent literature 5, the first insulating layer is used to flatten and fine irregularities on the first electrode are flattened with a thin second insulating layer made of a silicon oxide film or a silicon nitride film, that is, a two layer structure is taken. Accordingly, there are problems in that many labor hours are necessary, a tunnel current may be generated and, since the second insulating layer has to be formed so as to flatten the fine irregularities on the first electrode while controlling a film thickness with high accuracy, the productivity is poor.

Furthermore, in the organic electroluminescent element of patent literature 4, although a metal oxide thin film is assumed to use, it is formed separately for every element.

### SUMMARY OF THE INVENTION

The invention was carried out in view of the foregoing circumstances and intends to provide an organic electroluminescent device that can be driven in a wide range from low brightness for display use to high brightness for light sources.

In order to achieve the foregoing object, the invention is an organic electroluminescent device with a plurality of light emitting portions on a substrate, the light emitting portion including: a pair of electrodes; a light emitting layer interposed between the electrodes; and a transition metal oxide layer disposed between at least one of the electrodes and the light emitting layer, wherein the transition metal oxide layer is formed over the plurality of light emitting portions.

According to the configuration, an organic electroluminescent device extremely large in the emission intensity and stable in the characteristics can be obtained.

### BRIEF DESCRIPTION OF THE DRAWINGS

FIG. 1 is a schematic sectional view of an organic electroluminescent device of a first embodiment of the invention,

FIGS. 2A through 2C are explanatory diagrams of an organic electroluminescent device of the first embodiment of the invention,

FIGS. 3A through 3D are production process charts of an organic electroluminescent device of the first embodiment of the invention,

FIG. 4 is an equivalent circuit diagram of an active matrix display device of the first embodiment of the invention,

FIG. 5 is a layout explanatory diagram of a display device of the first embodiment of the invention,

FIG. 6 is a sectional view of a display device of the first embodiment of the invention,

FIG. 7 is a top surface explanatory diagram of a display device of the first embodiment of the invention,

FIG. 8 is a schematic sectional view of an optical head of the first embodiment of the invention,

FIG. 9 is a schematic sectional view of an optical head of the first embodiment of the invention,

FIG. 10 is a schematic sectional view of an organic electroluminescent device of a second embodiment of the invention,

FIG. 11 is a schematic sectional view showing an essential portion of a modification example of an organic electroluminescent element in a third embodiment of the invention and

FIGS. 12A through 12D are production process charts of an organic electroluminescent element of a fourth embodiment of the invention.

### DETAILED DESCRIPTION OF THE PREFERRED EMBODIMENTS

In what follows, embodiments of the invention will be detailed with reference to the drawings.

### First embodiment

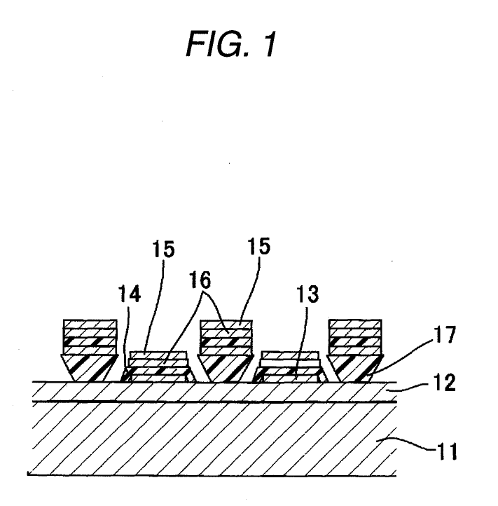

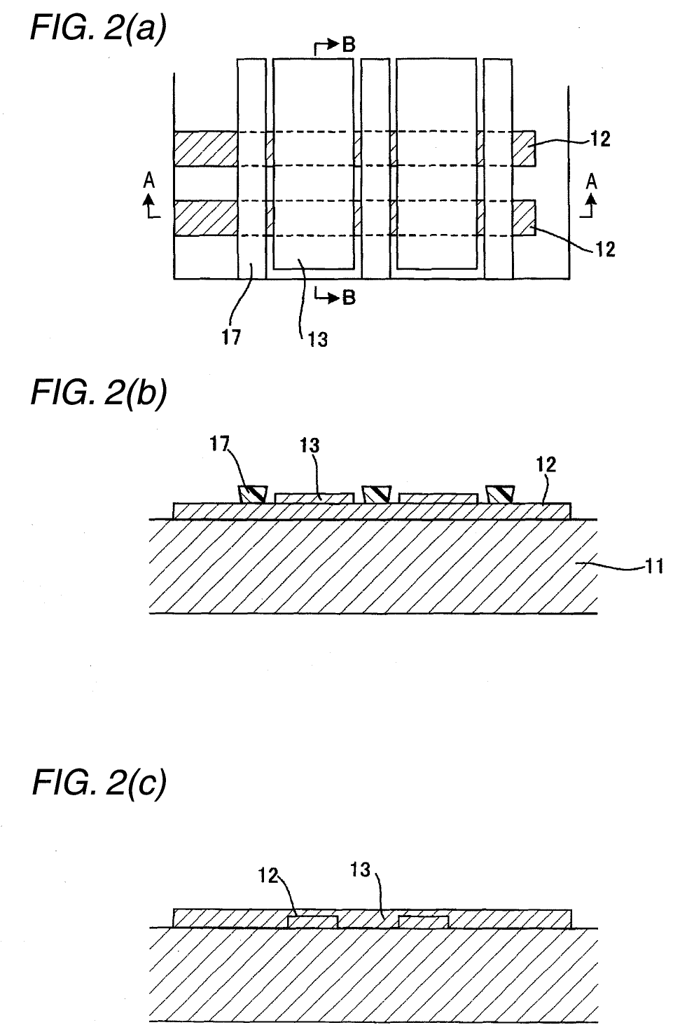

FIG. 1 is a sectional view showing a configurational diagram of an organic electroluminescent device having a structure where polymer organic electroluminescent elements in an embodiment of the invention are arranged in matrix, FIG. 2A being a plan explanatory diagram showing a state before an electroluminescent layer of the organic electroluminescent device is formed, FIG. 2B being an A-A section diagram of FIG. 2A, and FIG. 2C being a B-B section diagram of FIG. 2A.

The embodiment constitutes a top emission type organic electroluminescent element in which on an anode 12 made of an aluminum layer formed in stripe as a reflective metal formed on a translucent glass substrate 11, a transition metal oxide (molybdenum oxide) layer as a charge injection layer 13 is formed in stripe in a direction perpendicular to the striped anode 12 (FIG. 2A), thereon a polymer layer (not shown in the drawing) as an organic buffer layer having an electron blocking function and a polymer as a light-emitting layer 14 are sequentially laminated, and further thereon a transition metal oxide (molybdenum oxide) layer as a buffer layer 16 and a cathode 15 formed of indium tin oxide (ITO) that is a translucent material are sequentially laminated. An intersection region of stripe-formed anode 12 and cathode 15 constitutes a light emitting portion. A reference numeral 17 denotes a partition wall formed of a resist, that is, a protrusion having a trapezoidal cross section as a pixel restricting layer.

Like this, a first embodiment is an organic electroluminescent device provided with a plurality of light emitting portions on a substrate (glass substrate 11), the light emitting portion including: a pair of electrodes (anode 12, cathode 15); a light emitting layer 14 interposed between the electrodes; and a transition metal oxide layer (charge injection layer 13 or buffer layer 16) disposed between at least one of the electrodes and a light emitting layer 14, wherein, as shown in FIG. 2A, the transition metal oxide layer is formed over a plurality of light emitting portions. However, FIG. 2A shows a state before the light emitting layer 14 is formed; accordingly, different from FIG. 1, as the transition metal oxide layer, only the charge injection layer 13 is depicted.

When particular anode 12 and cathode 15 of an organic electroluminescent element having such a configuration are selected and a DC voltage or DC current is applied with the anode 12 as a plus electrode and the cathode 15 as a minus electrode, in a light emitting layer 14 made of a polymer film formed at an intersection region of the anode 12 and cathode 15 formed by use of for instance an inkjet method or a coating method such as a printing method, from the anode 12, through a charge injection layer 13 and an organic buffer layer (not shown in the drawing), holes are injected and at the same time, from the cathode 15, through the buffer layer 16, electron are injected. In the light emitting layer 14, thus injected holes and electrons recombine and, when resultantly generated excitons return from an excited state to a ground state, a luminescent phenomenon is caused.

According to an organic electroluminescent element of the first embodiment, on the glass substrate 11, a layer of aluminum that is a reflective metal is formed as an anode 12, and between the anode 12 and the light emitting layer 14 and between the cathode 15 on an upper layer side and the light emitting layer 14, a buffer layer 16 made of a molybdenum oxide thin film is interposed. Accordingly, a striped pattern that constitutes the anode 12 is flattened by the charge injection layer 13 formed on an upper layer thereof in stripe in a direction perpendicular to the striped pattern (as to the state, refer to FIG. 2C), and on the upper layer a light emitting layer 14 is formed. A buffer layer 16 made of a molybdenum oxide layer is formed so as to cover on the light emitting layer 14 to further flatten a surface, and further thereon the cathode 15 is formed.

Thus, when a charge injection layer 13 made of a transition metal oxide is formed so as to continuously straddle on a plurality of anodes 12 formed in stripe, even when a step is generated at an edge portion of the anode 12, the flattening can be achieved. The light emitting layer 14 is formed on the charge injection layer 13 thus integrally formed over a plurality of light emitting portions (plural pixels), further through a buffer layer 16 integrally formed on the top layer of the light emitting layer 14 a cathode 15 is formed, resultantly the light emitting layer 14 has a uniform film thickness in a light emitting portion formed in an intersection region of the anode 12 and cathode 15. Accordingly, in an edge portion of for instance the anode 12, the electric field concentration generated owing to thinning of a film thickness of the light emitting layer 14 can be avoided, resulting in an improvement in the emission characteristics and longer lifetime.

Furthermore, since, before the cathode 15 is formed, a surface of the light emitting layer 14 is covered with the buffer layer 16 made of a molybdenum oxide thin film, sputtering particles can be inhibited from damaging during deposition and thereby an excellent surface state can be maintained. According to the configuration, a top emission type organic electroluminescent element high in the reliability can be formed.

Furthermore, since the buffer layer 16 made of a molybdenum oxide thin film is formed between the cathode 15 and light emitting layer 14, excellent electron injection characteristics can be exerted. Still furthermore, since the charge injection layer 13 formed on the anode 12 is constituted of a molybdenum oxide thin film, holes can be readily injected from the anode 12 and an organic buffer layer (not shown in the drawing) disposed on the charge injection layer 13 can block an electron punch-through phenomenon from occurring; accordingly, holes and electrons can effectively contribute to emission in the light emitting layer 14.

Accordingly, excellent emission characteristics can be obtained and, even under high temperatures, an organic electroluminescent element high in the reliability can be obtained. Furthermore, molybdenum oxide used in the buffer layer 16 is substantially transparent in a visible light region. Accordingly, there is a large advantage in that, even when a film thickness fluctuates a little, the charge injection characteristics are not so much affected.

Furthermore, as will be described below, even when, on a base, a driving thin film transistor is formed or a thin film transistor for detecting a light amount is formed, emission of the organic electroluminescent element, without being disturbed, can be excellently extracted outside thereof.

Hereinafter, an assemblage of the organic electroluminescent elements will be called an organic electroluminescent device.

In the next place, a producing process of an organic electroluminescent device of the invention will be described.

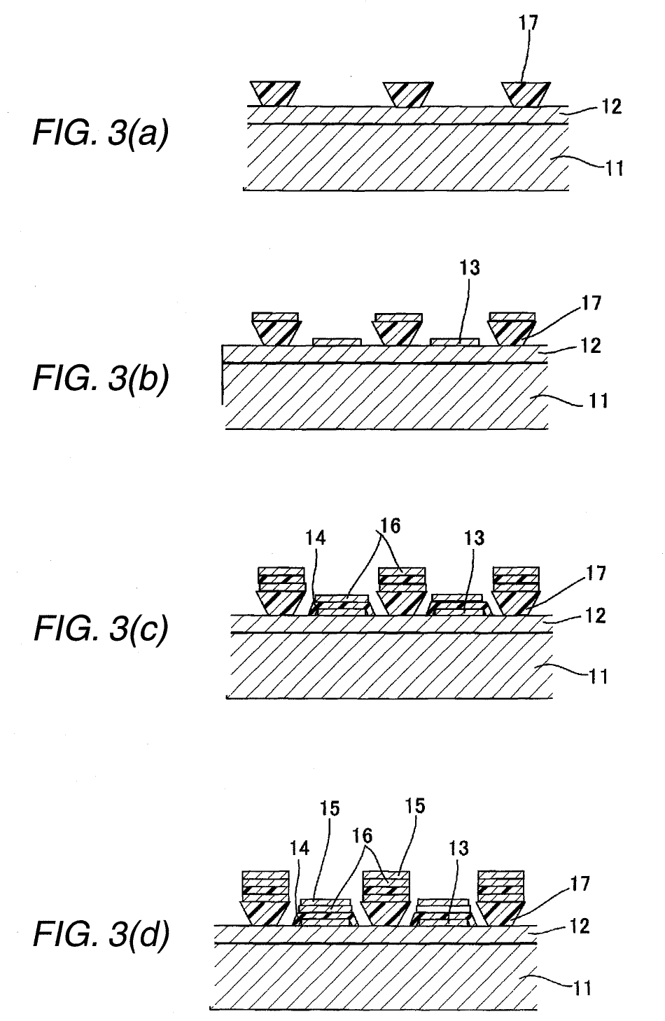

In the beginning, on a glass substrate 11, an Al thin film is formed by means of the sputtering method, followed by patterning this by applying a photolithography method to form an anode 12. On a top layer thereof, a resist is coated and, as shown in FIG. 3A, by means of the photolithography, a protrusion having a trapezoidal cross section is formed as a pixel restricting layer 17. At this time, an exposure light amount in the photolithography is controlled so as to form a trapezoidal cross section.

Thereafter, as shown in FIG. 3B, on a top layer thereof, by use of the vacuum deposition method, a molybdenum oxide thin film is formed, followed by patterning these by means of the photolithography to form a charge injection layer 13.

Thereafter, by means of the coating method, as shown in FIG. 3C, an organic buffer layer (not shown in the drawing) and a light emitting layer 14, which are made of a polymer, are coated and formed.

Further thereafter, as shown in FIG. 3D, by means of the vacuum deposition method, as a buffer layer 16, a molybdenum oxide thin film is formed.

At the last, sputtering particles are irradiated by means of the sputtering method to form an ITO thin film as a cathode 15.

Thus, an organic electroluminescent device shown in FIG. 1 is formed. According to the inventive method, the sputtering damage of the light emitting layer in a formation process of the cathode 15 can be excellently evaded owing to the buffer layer 16 and thereby an excellent surface state can be maintained. Furthermore, the organic buffer layer and light emitting layer 14 are formed by coating a polymer; accordingly, the production is easy and a large area can be obtained.

In the next place, specific examples of the first embodiment will be described.

A structure of an organic electroluminescent element in the specific example, being same as that shown in FIG. 1, will be described with reference to FIG. 1.

An organic electroluminescent device includes: a 1 mm-thick glass substrate 11 called Corning 7029#; an anode 12 formed thereon from an Al thin film having a thickness of 100 nm; a charge injection layer 13 made of a 50 nm-thick molybdenum oxide thin film formed on a top layer of the anode 12; poly[(9,9-dioctylfluorenyl-2,7-diyl)-alto-co-(N,N′-diphenyl)-N,N′di(p-butyl-oxyphenyl)-1,4-diaminobenzene] as an organic buffer layer that is a 20 nm-thick polyfluorene compound formed on the charge injection layer 13; a light emitting layer 14 made of 80 nm-thick poly[2-methoxy-5-(2-ethylhexyloxy)-1,4-phenylene vinylene] that is a PPV based material; a buffer layer 16 made of a 10 nm-thick molybdenum oxide thin film formed on the light emitting layer 14; and a cathode 15 made of a 100 nm-thick indium tin oxide (ITO) layer. Thus prepared sample was rendered a sample 101.

A thus formed organic electroluminescent element that uses molybdenum oxide as a charge injection layer is called hereinafter a “molybdenum oxide light emitting device”.

Furthermore, as shown in (Table 1), a sample where a charge injection layer was made of vanadium oxide (sample 102) and a sample where a charge injection layer was made of tungsten oxide (sample 103) were similarly prepared. 19.

TABLE 1

| 1) | | 2) | | 3) | 4) | 5) | 6) | Cathode | | | 7) | 8) | 9) |
|---|---|---|---|---|---|---|---|---|---|---|---|---|---|
| 101 | 10) | Al (100) | None | MoO₃ | PF | PF | MoO₃ | None | ITO | | None | 4900 | 200 |
| | | | | (10) | (20) | (80) | (2) | | (100) | | | | |
| 102 | 11) | Al (100) | None | VO₃ | PF | PF | MoO₃ | None | ITO | | None | 4900 | 200 |
| | | | | (10) | (20) | (80) | (2) | | (100) | | | | |
| 103 | 12) | Al (100) | None | WO₃ | PF | PF | MoO₃ | None | ITO | | None | 4900 | 200 |
| | | | | (10) | (20) | (80) | (2) | | (100) | | | | |
| 201 | 13) | Al (50) | None | MoO₃ | PF | PF | None | None | ITO | | Yes | 17) | — |
| | | | | (10) | (20) | (80) | | | (100) | | | | |
| 202 | 14) | Al (50) | None | MoO₃ | PF | PF | None | Ba (2) | Au (10) | | Yes | 2000 | 60 |
| | | | | (10) | (20) | (80) | | | | | | | |
| 203 | 15) | Al (50) | None | MoO₃ | PF | PF | None | Ba (2) | Al (2) | ITO | Yes | 4200 | 65 |
| | | | | (10) | (20) | (80) | | | | (100) | | | |
| 204 | 16) | Al (50) | None | PEDT | PF | PF | CuPc | Ba (2) | ITO | | Yes | 3200 | 80 |
| | | | | | (20) | (80) | (2) | | (100) | | | | |

1) Sample No.
2) Reflective Copper and Anode
3) Hole Injection Layer
4) Organic Buffer Layer
5) Organic Luminescent Layer
6) Buffer Layer
7) Crosstalk
8) Brightness
9) Half Brightness Life (Hr), @ 10,000 Cd
10) Present Invention 1
11) Present Invention 2
12) Present Invention 3
13) Comparative Example 1
14) Comparative Example 2
15) Comparative Example 3
16) Comparative Example 4
17) Large Irregularity

Furthermore, electroluminescent devices formed without a molybdenum oxide thin film of the light emitting device shown in FIG. 1 (samples 201 through 203) were prepared as comparative examples 1 through 3. Still furthermore, for the sake of comparison, a charge injection layer formed on the anode (hole injection layer) was formed from PEDOT and between the light emitting layer and the buffer layer copper phthalocyanine was formed as the buffer layer. The organic electroluminescent devices were connected to a DC power source, followed by raising a voltage to measure the emission brightness at 6 V. As the result, the molybdenum oxide light emitting device of the sample 101 shown in example 1 and the light emitting devices of samples 102 and 103, respectively, without showing the crosstalk, showed the emission brightness of substantially 4900 cd/m², 2800 cd/m² and 3800 cd/m². On the other hand, the devices of comparative examples showed the emission brightness of substantially 2000 cd/m² lower than that of samples 101 through 103 and some of these showed larger brightness fluctuation. Furthermore, even in one such as comparative example 3 (sample 203) that showed such large brightness as substantially 4200 cd/m², it was found that the half brightness life was such short as substantially 65 hr.

When the ITO that constitutes the cathode 15 was formed by means of the sputtering method, the sputter damage of the light emitting layer 14 could not be avoided. However, as mentioned above, when a molybdenum oxide layer is interposed as well on the cathode 15 side, the sputtering damage can be avoided, a surface state of the light emitting layer 14 can be maintained excellent, and the molybdenum oxide layer forms an ohmic contact with the light emitting layer 14. Accordingly, without depending on the work function of an electrode material that constitutes the cathode 15, the electron injection characteristics can be improved and the hole blocking performance can be improved.

In particular, in the organic electroluminescent element, a transition metal oxide layer formed between the second electrode (electrode that is formed after the light emitting layer 14 is formed and corresponds to the cathode 15 in first embodiment) and the light emitting layer 14 or a second transition metal oxide layer is desirably formed so as to cover the light emitting layer 14.

According to such the configuration, when the second electrode is deposited or patterned, the light emitting layer 14 is covered with a transition metal oxide layer; accordingly, the light emitting layer 14 is protected from the sputter damage or plasma damage and thereby a film high in the reliability can be formed.

Furthermore, when, for the sake of comparison, a charge injection layer (hole injection layer) formed on the anode 12 is formed of PEDOT and copper phthalocyanine is formed as a buffer layer between the light emitting layer 14 and the cathode 15 (sample 204 (comparative example 4)), not only the brightness was deteriorated to 3200 Cd/m², but also the brightness half life became less than half such as from 200 hr to 80 hr.

In the foregoing description, the organic light emitting layer was DC-driven. However, an AC voltage or AC current or a pulse wave can be used to drive.

Since a thickness of a transition metal oxide, in particular, a film thickness of MoO₃ is very insensitive to the element characteristics, an organic electroluminescent element that can be, without largely depending on the thickness, stably operated with uniform luminescence characteristics can be provided. Furthermore, owing to the stability, on a top layer thereof, a layer having a light emitting function can be formed by means of a vapor deposition method and the light emitting layer 14 can be formed with a low molecular layer as well. Still furthermore, when a transition metal oxide layer having a film thickness of at least 30 nm or more or desirably 40 nm or more is contained, even when a resist remains or particles stick on ITO when a translucent electrode such as the ITO is patterned, owing to the formation of a 30 nm-thick or more and desirably 40 nm-thick or more transition metal oxide layer, a layer having a light emitting function formed thereon can be uniformly formed without causing a film thickness distribution. Accordingly, without generating a non-emitting region or pixel short-circuiting, a layer having a uniform emitting function can be formed and excellent emission spectrum can be obtained. Furthermore, when a transition metal oxide such as MoO₃ is layered, by selecting conditions, a transition metal oxide layer small in the specific resistance in a lamination direction can be obtained; accordingly, even when a film thickness is made thicker, without causing a large voltage drop, an electric field can be applied to a layer having an emitting function. Here, as the transition metal oxide, molybdenum oxide, vanadium oxide or tungsten oxide can be applied. However, as molybdenum oxide (MoOₓ), without restricting to MoO₃, ones having different valences (MoₓO_{y}) are effective as well. As to vanadium oxide and tungsten oxide, ones having different valences can be effectively used. Furthermore, oxides formed by co-deposition and containing a plurality of elements can be applied as well.

As transition metal oxides that are used here, other than molybdenum oxide, oxides of chromium (Cr), tungsten (W), vanadium (V), niobium (Nb), tantalum (Ta), titanium (Ti), zirconium (Zr), hafnium (Hf), scandium (Sc), yttrium (Y), thorium (Th), manganese (Mn), iron (Fe), ruthenium (Ru), osmium (Os), cobalt (Co), nickel (Ni), copper (Cu), zinc (Zn), cadmium (Cd), aluminum (Al), gallium (Ga), indium (In), silicon (Si), germanium (Ge), tin (Sn), lead (Pb), antimony (Sb), bismuth (Bi) or so-called rare earth elements from lanthanum (La) to lutetium (Lu) can be cited. Among these, aluminum oxide (AlO), copper oxide (CuO) and silicon oxide (SiO) are particularly effective from the viewpoint of long lifetime.

Furthermore, when, as electrode materials that constitute the anode 12, other than aluminum shown in example 1, electrode materials such as silver, copper, copper alloys and chromium that have the work function smaller than that of the light emitting layer 14 is used, an organic electroluminescent element that is, while maintaining sufficient reflectance, excellent in the emission characteristics and high in the reliability can be provided.

Silver is low in the resistance, can be formed as a coated film and has the reflectivity; accordingly, it can be formed in the same process as that of a wiring pattern and, in the integration, is a very effective material. However, since its work function is such small as substantially 4.73 eV, silver is not used in an existing organic electroluminescent element as the anode 12. However, it was found that, when, like the first embodiment, a layer of a transition metal oxide such as molybdenum oxide was used as the charge injection layer 13, excellent emission characteristics could be obtained and thereby a top emission organic electroluminescent element could be formed. According to the foregoing configuration, as the anode 12, a silver or silver alloy layer that is low in the resistance and has the reflectivity can be used; accordingly, an organic electroluminescent element excellent in the emission characteristics can be formed.

Furthermore, copper is very low in the resistance, can be formed as a coated film and has the reflectivity; accordingly, at the integration, it can be formed in the same process as that of a wiring pattern to be a very effective material. However, since its work function is such small as substantially 4.1 through 4.5 eV, copper is not used in an existing organic electroluminescent element as the anode 12. However, when a layer of a transition metal oxide such as molybdenum oxide is used as the charge injection layer 13, excellent emission characteristics can be obtained and thereby a top emission organic electroluminescent element can be formed.

Although an anode material being used is different dependent on the ionization potential of the light emitting layer 14, materials smaller in the work function than the ionization potential of the light emitting layer 14 can be used. Other than the above-mentioned ones, gold (4.3 eV), molybdenum (4.6 eV), nickel (5.2 eV), tungsten (4.6 eV), indium (4.1 eV) and iridium can be selected considering only the specific resistance, adhesiveness with an adjacent layer and easy film formability.

Furthermore, in the first embodiment, as the light emitting layer 14, without restricting to PPV (polyphenylene vinylene) described in example 1, polymers having a dendrimer structure, a group of polyfluorene based compounds and derivatives thereof, a group of polyspiro compounds and derivatives thereof, so-called pendant polymers where a low molecular light emitting material is chemically bonded to a polymer skeleton, mixtures of a polymer organic EL material and a low molecular organic EL material and blends thereof can be used by appropriately altering. Still furthermore, coating type low molecular compounds can be applied as well. That is, a material of the light emitting layer is not particularly restricted.

That is, as a polymer based organic light emitting material that constitutes the light emitting layer 14, one that has the fluorescent or phosphorescent characteristics in the visible region and is excellent in the layering properties is desirable. For instance, a polymer light emitting material having a polyspiro ring as a skeleton can be preferably used and polymer light emitting materials such as polyparaphenylene vinylene (PPV) and polyfluorene can be used as well.

In formula (I), polyfluorene and derivatives thereof (R1 and R2, respectively, represent a substitution group) are shown.

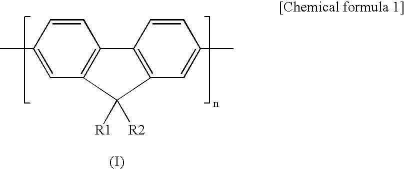

Furthermore, in formula (II), polyphenylene vinylene and derivatives thereof (R3 and R4, respectively, represent a substitution group) are shown.

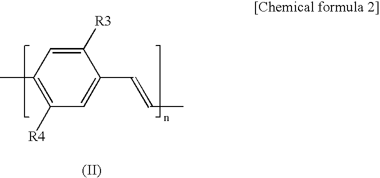

Furthermore, examples of low molecular organic light emitting materials that constitute the light emitting layer 14 include, other than Alq3 and Be-benzoquinolinol (BeBq2), benzoxazole compounds such as 2,5-bis(5,7-di-t-pentyl-2-benzoxazolyl)-1,3,4-thiaziazole, 4,4′bis(5,7-pentyl-2-benzoxazolyl)stilbene, 4,4′-bis[5,7-di-(2-methyl-2-butyl)-2-benzoxazolyl]stilbene, 2,5-bis(5,7-di-t-pentyl-2-benzosazolyl)thiophene, 2,5-bis([5-α,α-dimethylbenzyl]-2-benzoxazolyl)thiophene, 2,5-bis[5,7-di-(2-methyl-2-butyl)-2-benzoxazolyl]-3,4-diphenylthiophene, 2,5-bis(5-methyl-2-benzoxazolyl)thiophene, 4,4′-bis(2-benzoxazolyl)biphenyl, 5-methyl-2-[2-[4-(5-methyl-2-benzoxasazolyl)phenyl]vinyl]benzoxazolyl and 2-[2-(4-chlorophenyl)vinyl]naphto[1,2-d]oxazol; benzothiazole compounds such as 2,2′-(p-phenylenedivinylene)-bisbenzothiazole; fluorescent brightening agents such as benzimidazole compounds such as 2-[2-[4-(2-benzimidazolyl)phenyl]vinyl]benzoimidazole and 2-[2-(4-carboxyphenyl)vinyl]benzoimidazole; 8-hydroxyquinolin metal complex such as tris(8-quinolinol)aluminum, bis(8-quinolinol)magnesium, bis(benzo[f]-8-quinolinol)zinc, bis(2-methyl-8-quinolinolate)aluminum oxide, tris(8-quinolinol)indium, tris(5-methyl-8-quinolinol)aluminum, 8-quinolinol lithium, tris(5-chloro-8-quinolinol)gallium, bis(5-chloro-8-quinolinol)calcium and poly[zinc-bis(8-hydroxy-5-quinolinolyl)methane] or metalchelate oxynoid compounds such as dilithiumepindrizion; styrylbenzene compounds such as 1,4-bis(2-methylstyryl)benzene 1,4-(3-methylstyryl)benzene, 1,4-bis(4-methylstyryl)benzene, distyryl benzene, 1-4-bis(2-ethylstyryl)benzene, 1,4-bis(3-ethylstyryl)benzene and 1,4-bis(2-methylstyryl)-2-methyl benzene; distylpyrazine derivatives such as 2,5-bis(4-methylstyryl)pyrazine, 2,5-bis(4-ethylstyryl)pyrazine, 2,5-bis[2-(1-naphthyl)vinyl]pyrazine, 2,5-bis(4-methoxystyryl)pyrazine, 2,5-bis[2-(4-biphenyl)vinyl]pyrazine and 2,5-bis[2-(1-pyrenyl)vinyl]pyrazine; naphthalimide derivatives; perylene derivatives; oxadiazole derivatives; aldazine derivatives; cyclopenthadiene derivatives; styrylamine derivatives; coumarin derivatives; and aromatic dimethylidine derivatives. Furthermore, anthracene, salicylate, pyrene and coronene can be used. Alternatively, phosphorescent materials such as fac-tris(2-phenyl pyridine)indium can be used as well. Here, a light emitting layer 14 made of a polymer material or a low molecular material can be formed according to a method where one obtained by dissolving a material in a solvent such as toluene or xylene is formed in layer according to a spin coat method or an inkjet method and a solvent in a solution is volatilized.

Furthermore, as the light emitting layer 14, a dendrimer may be used. In particular, a dendrimer having a heavy metal element such as Ir at a center portion can phosphoresces at high emission efficiency. Depending on a structure of a dendron portion of a ligand, desired colors such as red, green and blue can be obtained. Similarly, according to a structural design having an electron transport portion and a hole transport portion, charge transportability can be controlled.

For instance, as a dendrimer that emits green phosphorescence, an indium dendrimer complex such as shown by a formula below can be cited.

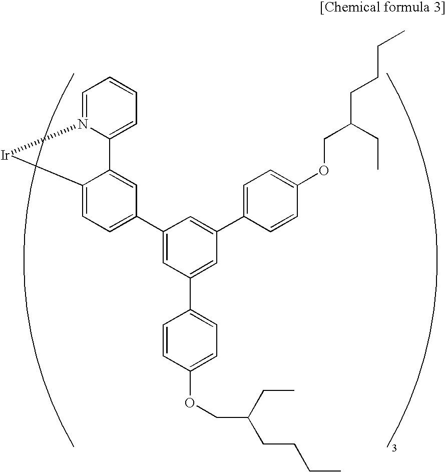

For instance, as a dendrimer that emits red phosphorescence, an indium dendrimer complex such as shown by a formula below can be cited.

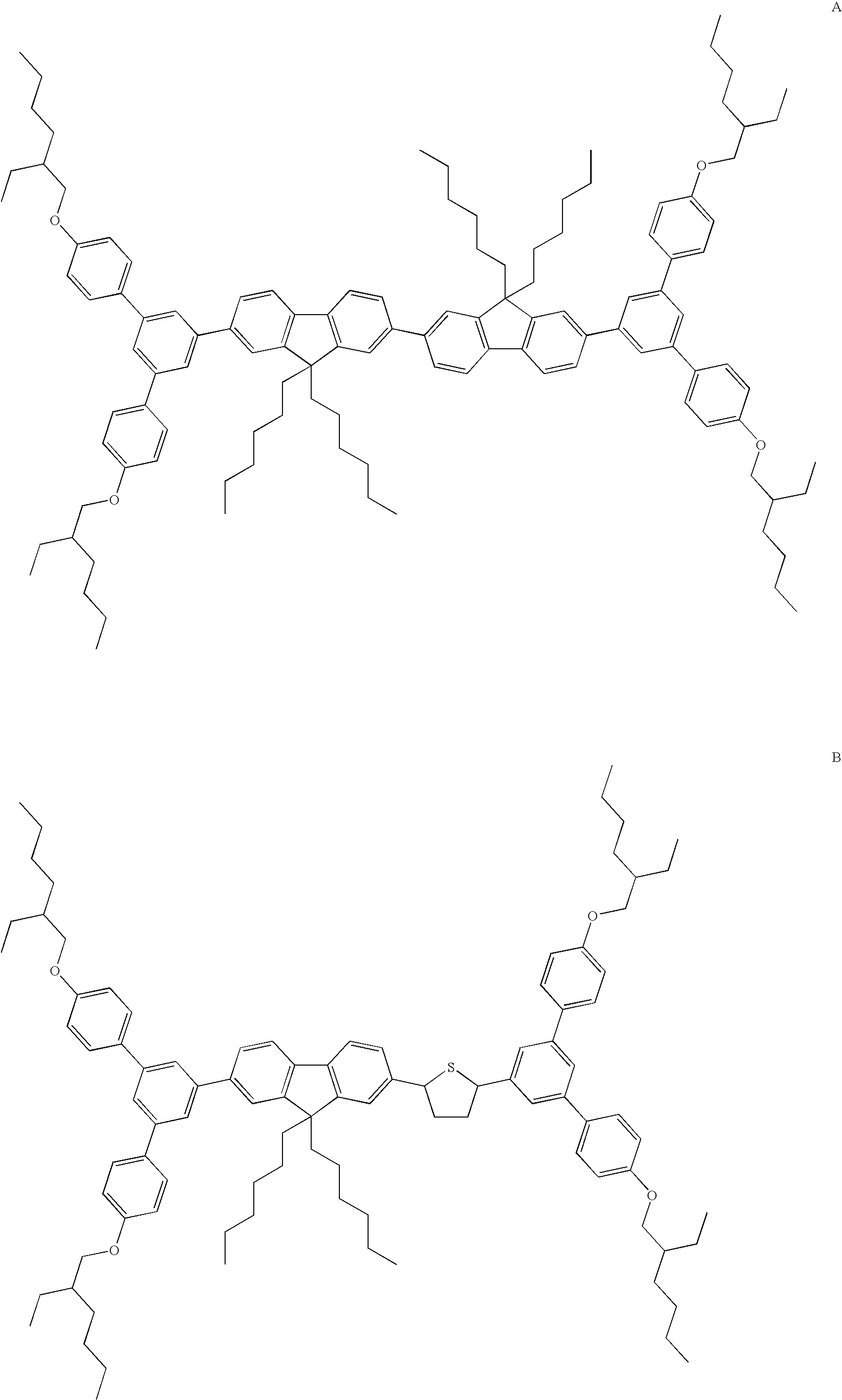

For instance, as a dendrimer that emits blue phosphorescence, an indium dendrimer complex such as shown by a formula below can be cited. The dendrimer is a complex constituted of a mixture of a dendrimer A that emits deep blue color and a dendrimer B that emits blue green color.

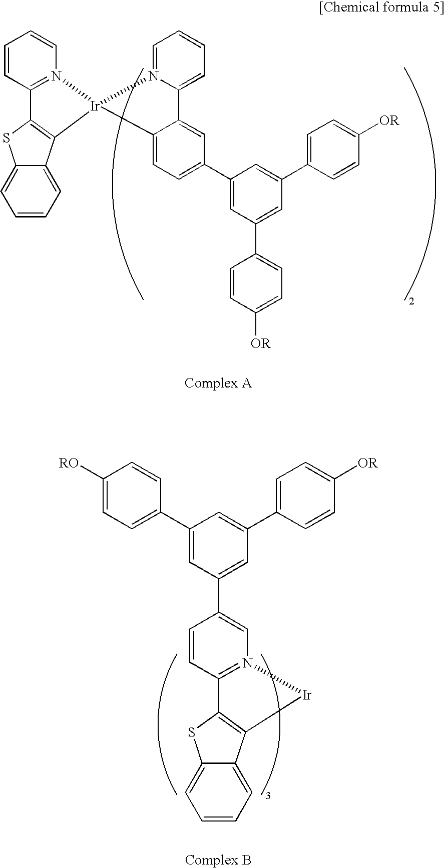

When a light emitting layer 14 is formed of a polymer (polymer material), even a large area can be uniformly layered; accordingly, a large area organic electroluminescent element can be prepared. Furthermore, since the thermal stability of the light emitting layer can be heightened and defects and pin holes in an interface between layers can be inhibited from occurring, an organic electroluminescent element high in the stability can be formed.

Furthermore, as the hole transport layer in the function layer, one that is high in the hole mobility and can be excellently layered is preferred. In addition to TPD, organic materials such as porphyrin compounds such as porphyrin, tetraphenylporphyrin copper, phthalocyanine, copper phthalocyanine and titanium phthalocyanine; aromatic tertiary amines such as 1,1-bis{4-(di-P-tolylamino)phenyl}cyclohexane, 4,4′,4″-trimethyltriphenylamine, N,N, N′,N′-tetrakis(P-tolyl)-P-Phenylenediamine, 1-(N,N-di-P-tolylamino)naphthalene, 4,4′-bis(dimethylamino)-2-2′-dimethyltriphenylmetane, N,N,N′,N′-tetraphenyl-4,4′-diaminobiphenyl, N,N′-diphenyl-N, N′-di-m-tolyl-4,4′-diaminobiphenyl and N-phenyl-carbazole; stilbene compounds such as 4-di-P-tolylaminostilbene and 4-(di-P-tolylamino)-4′-[4-(di-P-tolylamino)styryl]stilbene; triazole derivatives; oxadizazole derivatives; imidazole derivatives; polyarylalkane derivatives; pyrazoline derivatives; pyrazazolone derivatives; phenylenediamine devatives; anylamine derivatives; amino-substituted-chalcone derivatives; oxazole derivatives; styrylanthracene derivatives; fluorenone derivatives; hydrazone derivatives; silazane derivatives; polysilane based aniline copolymers; polymer oligomers; styrylamine compounds; aromatic dimethylidene compounds; and polythiophene derivatives such as poly-3,4-ethylenedioxythiophene (PEDOT), tetradihexylfluorenyl (TFB) or 3-methylthiophene (PMeT) can be used. Furthermore, a polymer dispersed hole transport layer in which a low molecular organic material for a transport layer is dispersed in a polymer such as polycarbonate can be used as well. The hole transport materials can be used as well as an electron blocking material.

As the electron transport layer in the function layer, a polymer material made of an oxadiazole derivate such as 1,3-bis(4-tert-butylphenyl-1,3,4-oxadiazolyl)phenylene (OXD-7), an anthraquinodimethane derivative, a diphenyl quinine derivative or a silole derivative; bis(2-methyl-8-quilinolate)-(para-phenyl phenolete) aluminum (BAlq) or bathocuproin (BCP) can be used. Furthermore, these materials which can form the electron transport layer may be used as a hole blocking material as well.

When the function layer (light emitting layer, or, hole injection layer or electron injection layer that is formed as needs arise) is formed of a polymer material, a wet film forming method such as a spin coat method, a casting method, a dipping method, a bar coat method, a printing method with a roll or an inkjet method can be used. Thereby, since a large vacuum unit becomes unnecessary, a cheap apparatus can be used to form a film, a large area organic electroluminescent element can be readily formed and the adhesiveness between the respective layers of the organic electroluminescent element can be improved; accordingly, an organic electroluminescent element that can inhibit the short-circuiting in the element from occurring and is high in the stability can be formed.

Furthermore, in order to use in a color display device, light emitting layers that realize emissions of the respective colors of RGB have to be separately coated. In this case, by use of a known printing method or an inkjet method, separate coating can be readily realized.

Still furthermore, as the cathode 15 of the organic electroluminescent element, a metal or alloy small in the work function is used. However, in order to constitute an organic electroluminescent element having a top emission structure, in the first embodiment, an ultra-thin film high in the light transmittance is formed with a metal small in the work function and thereon a conductive film made of a translucent material such as ITO or IZO is laminated to form a transparent cathode. As the ultra-thin film made of a material low in the work function, without restricting to a two-layer structure of Ba—Al, a two-layer structure of Ca—Al, a metal such as Li, Ce, Ca, Ba, In, Mg or Ti or an oxide thereof, a halide typical in fluoride, a Mg alloy such as a Mg—Ag alloy or Mg—In alloy, or an aluminum alloy such as an Al—Li alloy, Al—Sr alloy or Al—Ba alloy can be used. Alternatively, a lamination structure of an ultra-thin film having a lamination structure of LiO₂/Al or LiF/Al and a translucent conductive film as well can be preferably used as a cathode material.

Furthermore, in the first embodiment, for the sake of convenience, the light emitting layer 14 is described as a single layer. However, the light emitting layer 14 may have a three-layer structure where a hole transport layer/an electron blocking layer/the foregoing organic light emitting material layer (all are not shown in the drawing) are formed in this order from a side of the anode 12, a two-layer structure where an electron transport layer/an organic light emitting material layer (all are not shown in the drawing) are formed in this order from a side of the cathode 15, a two-layer structure where a hole transport layer/an organic light emitting material layer (all are not shown in the drawing) are formed in this order from a side of the anode 12 or a seven-layer structure where a hole injection layer/a hole transport layer/an electron blocking layer/an organic light emitting material layer/a hole blocking layer/an electron transport layer/an electron injection layer (all are not shown in the drawing) are formed in this order from an anode 12 side. Still furthermore, more simply, the light emitting layer 14 may have a single layer structure made of only the organic light emitting material. Thus, in the embodiment, what is called a light emitting layer 14 includes a case where the light emitting layer 14 has a multi-layer structure having function layers such as a hole transport layer, an electron blocking layer and an electron transport layer. The situation is same as well in other embodiments described below.

Still furthermore, among the function layers constituting an organic electroluminescent element of the invention, the transition metal oxide layer is not restricted in the deposition method to the foregoing methods. A dry process such as a vacuum deposition method, electron beam deposition method, molecular beam epitaxy method, sputtering method, reactive sputtering method, ion plating method, laser abrasion method, thermal CVD method, plasma CVD method or MOCVD method can be desirably used. Furthermore, when the respective function layers that constitute the organic electroluminescent element are layered, among wet methods such as a sol-gel method, Langmuir-Blodgett technique (LB technique), layer-by-layer method, spin coat method, inkjet method, dip coat method and spray method, an appropriate method can be selected. It goes without saying that as far as it can resultantly give birth to an advantage of the invention any one thereof can be used.

The glass substrate 11 is a solid plate of colorless transparent glass. As the glass substrate 11, transition metal oxide glass such as transparent or translucent soda lime glass, barium and strontium-containing glass, lead glass, aluminosilicate glass, borosilicate glass, barium borosilicate glass or quartz glass or inorganic glass such as inorganic fluoride glass can be used.

Other materials can be used in place of the glass substrate 11. That is, a polymer film that uses a polymer material such as transparent or translucent polyethylene terephthalate, polycarbonate, polymethyl methacrylate, polyether sulfone, polyvinyl fluoride, polypropylene, polyethylene, polyacrylate, amorphous polyolefin, fluorine-based resin polysiloxane or polysilane; chalcogenide glass such as As₂S₃, AS₄₀S₁₀ or S₄₀Ge₁₀; or metal oxide or nitride such as ZnO, Nb₂O, Ta₂O₅, SiO, Si₃N₄, HfO₂ or TiO₂ can be used. Alternatively, when light exited from an emission region is extracted without involving a substrate, a semiconductor such as non-transparent silicon, germanium, silicon carbide, gallium arsenide or gallium nitride, the transparent substrate containing a pigment or a metal on a surface of which an insulation process is applied can be appropriately selected and used. A laminated substrate in which a plurality of substrate materials is laminated can be used as well.

On a surface or inside of a substrate such as the glass substrate 11, as will be described below, circuits made of resistor, capacitor, inductor, diode and transistor for driving an electroluminescent element can be integrally formed.

Furthermore, depending on applications, a material allowing transmitting only a particular wavelength or a material having a light to light conversion function for converting to light having a particular wavelength may be used. The substrate is preferably insulative without particularly restricting. However, within a range that does not disturb to drive an electroluminescent element or depending on applications, the substrate may have the electroconductivity.

That is, in the first embodiment, a metal at least surface of which is reflective may be used to constitute. For instance, with a metal substrate, this may be used for instance as a grounding terminal. In this case, through an insulating film having a throughhole in a predetermined region, as an anode, aluminum is used to form a desired conductor pattern. An upper layer thereof is formed in an order of a transition metal oxide layer, a light emitting layer and an anode similarly to the foregoing embodiment.

Thus, a polymer organic electroluminescent element having a transition metal oxide layer as a charge injection layer on an anode formed on a substrate can maintain, over a wide current density range, the emission intensity and emission efficiency of the element at a high level and exhibits excellent lifetime characteristics. Accordingly, an organic electroluminescent element that can be stably operated over a wide brightness range and is excellent in the lifetime characteristics can be realized.

In the next place, a display device in which the foregoing organic electroluminescent device is applied will be described.

In a display device in which the first embodiment is applied, fundamentally, with a light emitting device similar to an organic electroluminescent device shown in FIG. 1, in which a molybdenum oxide layer is interposed on an anode 12 side as a function layer, an active matrix display device is constituted.

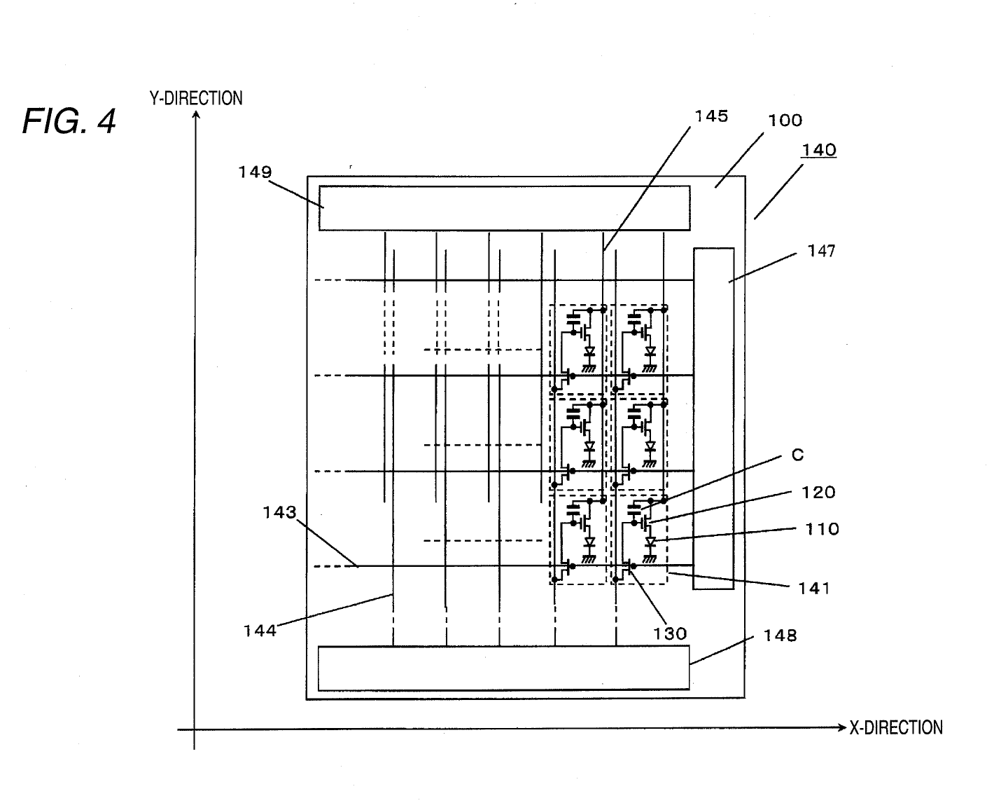

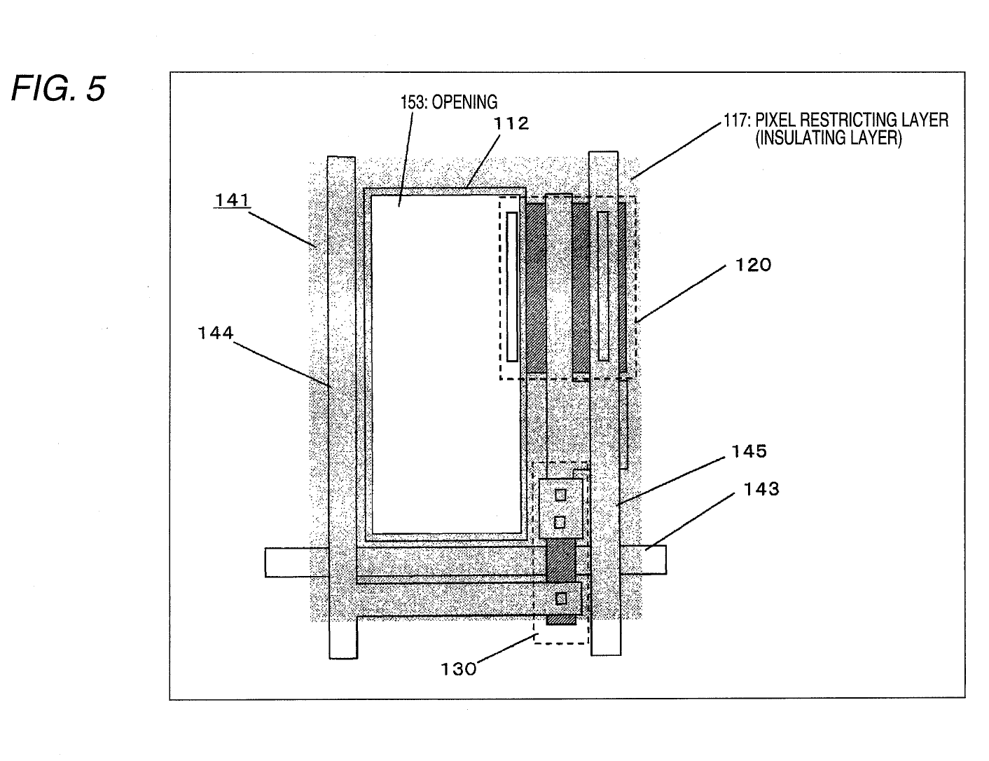

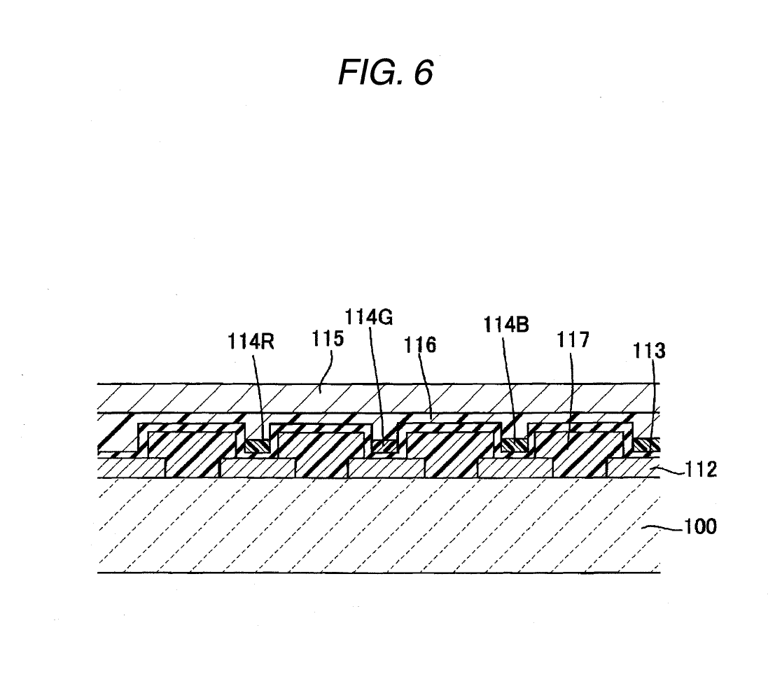

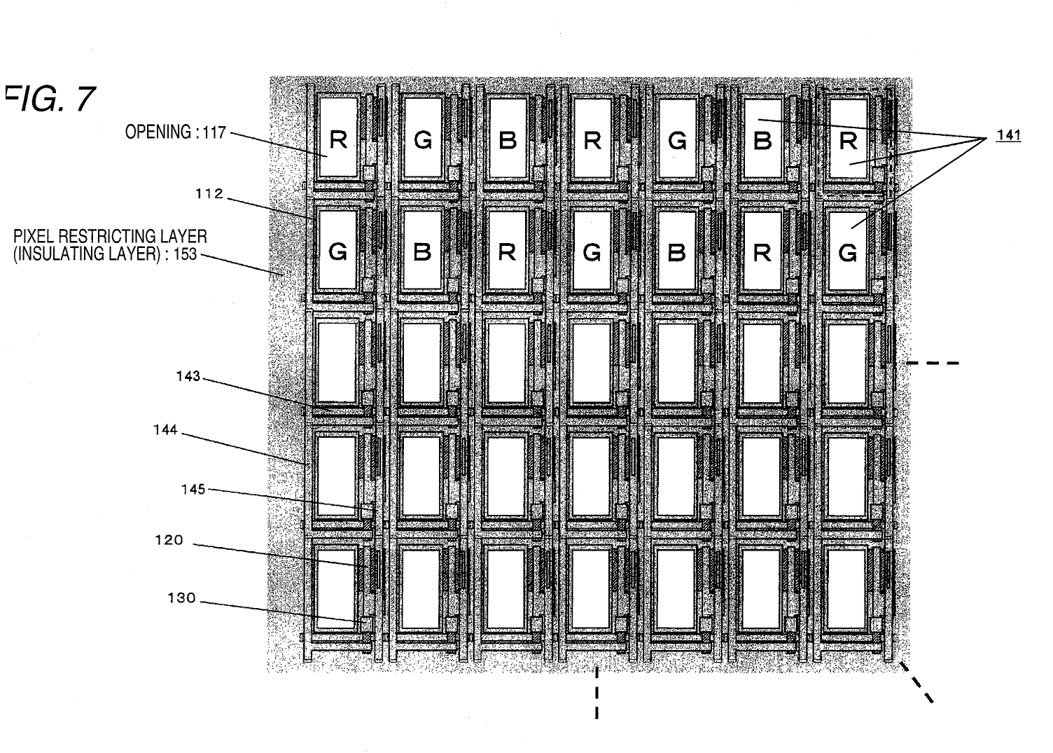

The display device, as an equivalent circuit of the active matrix display device, a layout explanatory diagram, a sectional diagram thereof and a top surface explanatory diagram, respectively, are shown in FIG. 4, FIG. 5, FIG. 6 and FIG. 7, constitutes an active matrix display device in which each pixel is provided with a driving circuit.

The display device 140, as an equivalent circuit and a layout explanatory diagram of pixels thereof, respectively, are shown in FIG. 4 and FIG. 5, is constituted in such a manner that a plurality of driving circuits each made of an organic electroluminescent element (electroluminescent element) 110 that constitutes a pixel, two TFTs (T1, T2) made of a switching transistor 130 and a current transistor 120 and a capacitor C is arranged from right to left and up and down, a gate electrode of a first TFT (T1) of each of the driving circuits arranged from right to left is connected to a scanning line 143 to give a scanning signal, and a drain electrode of a first TFT of the respective driving circuits arranged in an up and down direction is connected to a data line to supply an emission signal. To one end of the electroluminescent element, a driving power source (not shown in the drawing) is connected and one end of the capacitor is grounded. Reference numerals 143, 144, 145, 147, 148 and 149, respectively, denote a scanning line, a signal line, a common supply line, a scanning line driver, a signal line driver and a common supply line driver.

FIG. 6 is a sectional explanatory diagram of an organic electroluminescent element and FIG. 7 is a top surface explanatory diagram of the display device. On a glass substrate 100 on which driving thin film transistors (not shown in the drawing) are formed, an anode 112 made of aluminum, a molybdenum oxide layer as a charge injection layer 113, an organic buffer layer (charge blocking layer) (not shown in the drawing), a light emitting layer 114 (red emission layer 114R, green emission layer 114G and blue emission layer 114B), a molybdenum oxide layer as a buffer layer 116 and a cathode 115 are formed to form a top emission organic electroluminescent element. As a structure, an anode 112 and a charge injection layer 113 are formed individually, a light emitting layer 114 is restricted in an opening area by a protrusion made of a silicon oxide layer as a pixel restricting layer 117 and a buffer layer 116 and a cathode 115 are formed in stripe running in a direction perpendicular to the anode 112.

The driving thin film transistor is formed in such a manner that, for instance, on a glass substrate 100, an organic semiconductor layer (polymer layer) is formed, this is covered with a gate insulating film, thereon a gate electrode is formed and through a throughhole formed on the gate insulating film a source/drain electrode is formed (all are not shown in the drawing). Then, thereon a polyimide film is coated to form an insulating layer (flat layer), further thereon, as mentioned above, an anode (constituted of an electrode material such as silver, copper, copper alloy or chromium that is smaller in the work function than the light emitting layer 14) 112, a molybdenum oxide layer as a charge injection layer 113, an electron blocking layer (not shown in the drawing), an organic semiconductor layer such as a light emitting layer 114, a molybdenum oxide layer as a buffer layer 116, a cathode 115 having a two layer structure (a laminate of a Ba—Al ultra-thin film and ITO) are formed to form an organic electroluminescent element. In FIGS. 5 and 7, capacitors and wirings, though omitted from showing, are formed as well on the same glass substrate 100. A plurality of pixels made of TFTs and an organic electroluminescent element is formed in matrix on the same substrate to form an active matrix display device.

At the production, as shown in FIGS. 5, 6 and 7, an opening portion 153 is formed with a pixel restricting layer 117 constituted of a silicon oxide layer (insulating layer), furthermore, a charge injection layer (molybdenum oxide layer) 113 is formed integrally with an anode 112 exposed in a pixel restricting layer 117 and an opening portion 153, and in a position corresponding to the opening portion 153, by means of an inkjet method, light emitting layers 114R, 114G and 114B (FIG. 6) corresponding to the respective colors are formed.

That is, at the time of production, on a scanning line 143, a signal line 144, a switching TFT 130 and an anode 112 made of an aluminum pattern that constitutes a pixel electrode, which are formed on the glass substrate 100, a pixel restricting layer 117 is formed followed by disposing an opening portion.

Then, on a top layer thereof, over an entire surface, a charge injection layer 113 (transition metal oxide layer) is deposited by the vapor deposition to form.

Thereafter, by means of an inkjet method, as needs arise, TFB is coated as a buffer layer. The TFB layer may be coated over an entire surface similarly to the transition metal oxide layer or may be coated only to a portion corresponding to an opening portion.

Subsequently, by undergoing a drying process, to a position corresponding to an opening portion, by means of an inkjet method, a polymer organic EL material corresponding to a desired color (any one of RGB) is discharged to form a light emitting layer 114 (114R, 114G, 114B).

Furthermore, a buffer layer 116 is deposited, and finally to a region where a display pixel 141 is disposed, a not shown cathode 115 is formed.

According to the configuration, a display device that can be driven at high speed and is high in the reliability can be provided. Since a layer of molybdenum oxide (charge injection layer 113) that is a transition metal oxide that is formed integrally is interposed between a light emitting layer 114 and the anode 112, the crosstalk is not generated and a light emitting layer 14 is filled in a recess flattened by the molybdenum oxide layer and having an inner surface of which size is controlled with high precision. Accordingly, by use of an inkjet method, without causing the positional displacement, a light emitting layer 114 can be assuredly formed and thereby a light emitting layer 114 of which film thickness and size are controlled with high precision can be obtained. Furthermore, since on a top layer of the light emitting layer 114 as well, an integrally formed molybdenum oxide layer (buffer layer 116) is formed, when the cathode 115 is formed, the light emitting layer 114 is not sputter damaged, and in the patterning process, the plasma damage is not caused.

Accordingly, the light emitting layer 14 is formed on a uniformly formed surface and a surface can be maintained in a smooth state. As the result, the light emitting layer 14 is uniformly formed, without causing the electric field concentration an electric field applied by the anode 112 and the cathode 115 is uniformly applied to the light emitting layer 14, and thereby excellent light emitting characteristics can be obtained. Furthermore, the respective light emitting layers (114R, 114G, 114B) as well are uniformly formed; accordingly, excellent light emitting characteristics less in the fluctuation of the light emitting characteristics (for instance white balance) can be obtained.

Furthermore, when the cathode 115 is layered or patterned, the light emitting layer 114 is covered at least by the buffer layer 116 made of a molybdenum oxide layer; accordingly, the light emitting layer 114, being protected from the sputter damage or plasma damage, can be formed into a film high in the reliability. Here, as shown in FIG. 6, the buffer layer 116 and a molybdenum oxide layer on a lower layer side (charge injection layer 113) are formed integrally larger than a pattern of the light emitting layer 114 so as to cover the light emitting layer 114. That is, these are continuously formed over a plurality of light emitting portions.

In the next place, an example of an illuminating device that uses a light emitting device in which a plurality of electroluminescent elements is two-dimensionally arranged will be described with reference to FIGS. 6 and 7. Of two-dimensionally arranged electroluminescent elements 110, for instance, a configuration where all electroluminescent elements 1 are simultaneously turned on/turned off can be very readily realized. However, even in a configuration of simultaneously turning on/turning off like this, at least one electrode (for instance, pixel electrode constituted of aluminum (anode 112 of FIG. 6)) is preferably constituted isolated for individual electroluminescent element 1 units. This is because, even when there is a defect in a display pixel 141 for some reason, the defect remains on the display pixel 141 and thereby the production yield of all illuminating devices can be improved. The illuminating device having such a configuration can be applied in general lighting apparatus for homes. In this case, an illuminating device can be formed very thin; accordingly, not only on a ceiling but also on a wall surface, the illuminating device can be readily disposed.

Furthermore, when two-dimensionally arranged electroluminescent elements are provided with arbitrary data, an emission pattern thereof can be readily controlled. Still furthermore, since the electroluminescent element involving the invention can be formed in its emission region into a size of for instance substantially 40 μm square, when data are supplied to the illuminating device, an application that combines a panel type display device can be formed. In this case, it goes without saying that the display pixels 141 are necessarily separately coated in red, green and blue. However, by use of an inkjet method, multi-color display can be very readily realized.

So far, when an illuminating device and a display device are compared, the illuminating device is larger in the emission brightness. However, the electroluminescent element 110 of the invention can have a sufficiently large area and has very high emission brightness; accordingly, the electroluminescent element 110 of the invention can combine an illuminating device and a display device. In this case, the illuminating device and the display device, owing to difference of functions thereof (that is, application mode), necessitate a mechanism for controlling the emission brightness. The mechanism can be realized by controlling for instance a driving current to control the emission brightness of the respective electroluminescent elements. That is, when the electroluminescent element is used as an illuminating device, all electroluminescent elements are driven at a larger current and, when it is used as a display device, the respective electroluminescent elements may well be driven at a small current and current values controlled corresponding to gradations (that is, corresponding to image data). In such applications, a power source at the time of working as an illuminating device and a power source at the time of working as a display device may be a single one. However, when a driving current is controlled, for instance, when a dynamic range of a digital-analog converter is large to be deficient in the number of gradations when it is used as a display device, a configuration where a power source (not shown in the drawing) connected to a common supply line 145 shown in FIGS. 4 and 5 is switched corresponding to a usage mode is desired. Of course, in a usage mode as an illuminating device as well, a mode where the brightness has to be controlled (that is, illuminating device having a dimmer function) can be readily handled with the previously described current value control corresponding to the gradations. Furthermore, since the electroluminescent element of the invention can be formed not only on a glass substrate 100 but also on a resin substrate such as PET, it can be applied as illuminating devices for various illumination applications as well.

A thin film transistor may be formed of an organic transistor. Furthermore, a structure where an organic electroluminescent element is laminated on a thin film transistor or a structure where a thin film transistor is laminated on an organic electroluminescent element can be effectively used.

In addition, in order to obtain a high image quality electroluminescent display device, an electroluminescent substrate on which an organic electroluminescent element is formed and a TFT substrate on which a TFT, a capacitor and a wiring are formed may be adhered so that an electrode of the electroluminescent substrate and an electrode of the TFT substrate may be connected with a connection bank.

In the next place, an example where an organic electroluminescent device of the invention is applied in an optical head that is mounted on an image formation device will be described.

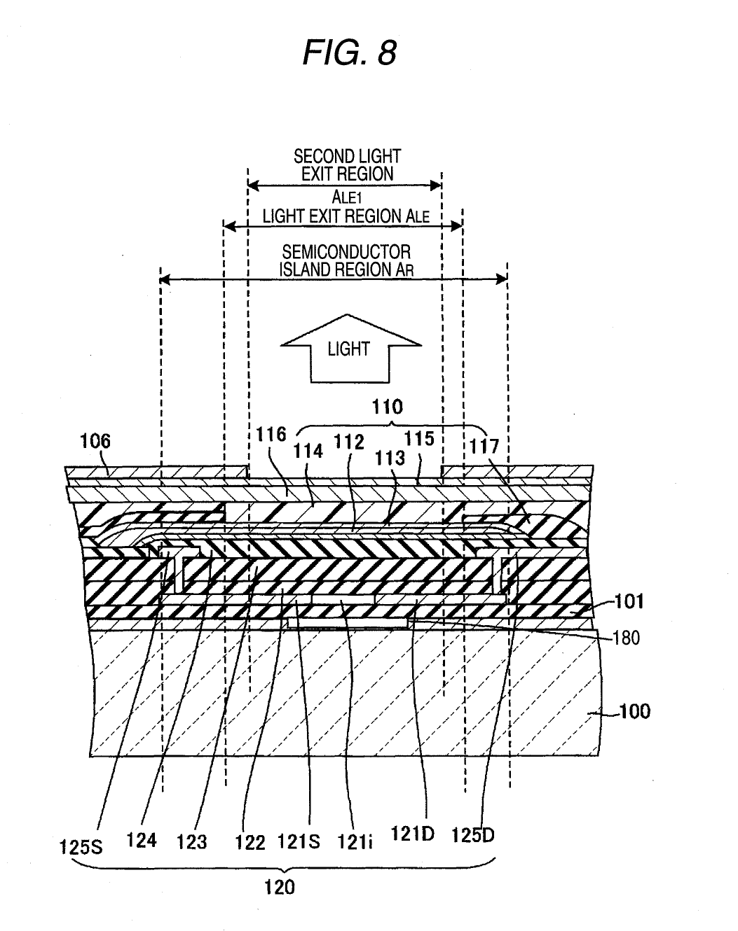

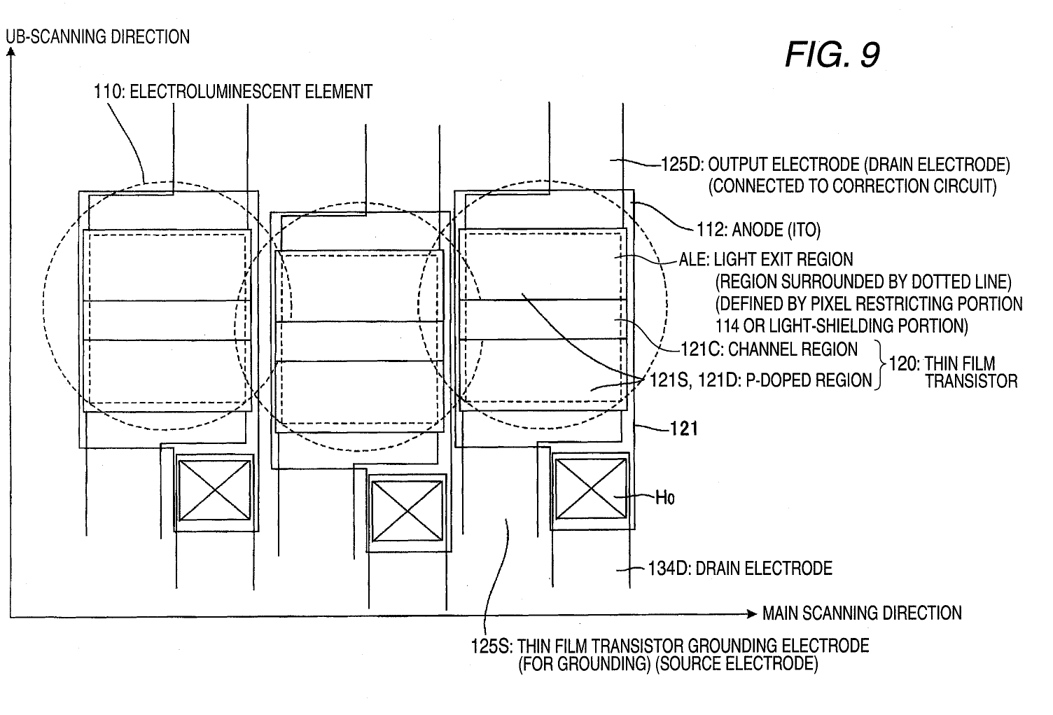

An optical head that uses an organic electroluminescent device in which first embodiment is applied, as a sectional schematic diagram is shown in FIG. 8 and a top view is shown in FIG. 9, is formed by sequentially laminating a thin film transistor as a driving transistor 120 and an electroluminescent device 110 on a glass substrate 100 on which a base coat layer (not shown in the drawing) is formed so as to flatten a surface. The driving transistor is a switching transistor that drives the electroluminescent device while correcting a driving current or a driving time in accordance with an output of a photodetector (not shown in the drawing) and, further on the glass substrate 100, a driving circuit (180) as an IC chip connected to the thin film transistor is mounted so as to locate at a lower layer of an organic electroluminescent device. A reference numeral 101 denotes an insulating film. The driving transistor 120 is constituted in such a manner that an island region AR made of a polycrystalline silicon layer formed on a surface of a base coat layer is doped at desired concentrations separated by a channel region made of a band-like i layer to form a source region 121S and a drain region 121D and, so as to penetrate through first and second insulating films 122 and 123 made of a silicon oxide film formed thereon, source and drain electrodes 125S and 125D that are made of a polycrystalline silicon layer are formed via throughholes. Furthermore, thereon, through a silicon nitride film as a protective layer 124, an electroluminescent device 110 is formed, and the respective layers of a protective layer 124, an Al layer that is an anode 112, a light emitting layer 114 and a cathode 115 are sequentially laminated in this order. A reference numeral 106 denotes a light shielding film having an opening for defining a light exit region as a second light exit region A_{LE1} inside of an actual light exit region A_{LE}. In actuality, although the drain electrode 125D and the anode 112 of the driving transistor 120 are connected, in FIG. 8, this is omitted from showing.

The respective layers are formed after going through ordinary semiconductor processes such as formation of a semiconductor thin film by use of a CVD method, patterning by means of photolithography, injection of an impurity ion and formation of an insulating film. The sheet resistance of the molybdenum oxide thin film in the first embodiment was measured by use of an ordinary four-terminal method and found to be 12 MΩcm.

An organic electroluminescent device in which, as shown in a sectional schematic diagram of FIG. 8, a molybdenum oxide layer having a film thickness of 40 nm is formed as a buffer layer 116 on a cathode 115 side as well is used. The electroluminescent device include, on a translucent glass substrate 100, an anode 112 made of a Cr layer as a first electrode, a cathode 115 as a second electrode made of ITO and a function layer formed between the electrodes. The function layer includes a layer that has an emission function and is made of an organic semiconductor polymer layer, that is, a light emitting layer 114, a molybdenum oxide layer having a film thickness of 40 nm formed as a charge injection layer 113 between the first electrode (anode 112) and the light emitting layer 114 and a pixel restricting layer 117 made of a silicon nitride layer having a film thickness of 50 nm formed at an lower layer of the charge injection layer 113, and the molybdenum oxide layer as the charge injection layer 113 and the buffer layer 116 being disposed between the first electrode and the light emitting layer and between the light emitting layer and the second electrode. The charge injection layer 113 and the buffer layer 116 are formed by use of a vacuum deposition method or a CVD method. When the CVD method is used, a composition ratio of raw material gases, pressure and temperature are controlled to deposit. Here, before the second electrode on an upper layer side is formed, a surface of the light emitting layer 114 has a molybdenum oxide layer as the buffer layer 116. Accordingly, even when the ITO as the second electrode is formed by use of the sputtering method, the light emitting layer 114 is not sputter damaged. Furthermore, the buffer layer 116 operates as an electron injection layer as well to improve the electron injection efficiency.

Furthermore, a transition metal oxide layer that constitutes the buffer layer 116 is deposited so that the specific resistance in a lamination direction may be substantially one third that in an in-plane direction. Still furthermore, a film thickness thereof is set at 40 nm that is a thickness that cannot be so far considered, thereby, a surface is flattened and smoothed owing to a thick molybdenum oxide layer and an area of an emission region is excellently regulated.

Here, between a thick molybdenum oxide layer as the buffer layer 116 and the first electrode made of an aluminum layer that is an anode 112, a buffer layer (electron blocking layer) made of TFB is interposed. However, the buffer layer can be done without.

According to the configuration, an organic electroluminescent device that is excellent in the injection efficiency and high in the reliability can be formed. On the other hand, when a PEDT layer was used in place of the transition metal oxide layer constituted of molybdenum oxide, the injection efficiency was not sufficient. Furthermore, when a transition metal oxide layer is formed with a film thickness of 40 nm, a surface can be flattened and smoothed owing to a thick MoO₃ film, and an area of an emission region can be excellently regulated. Still furthermore, a base of the pixel regulating layer can be smoothed, even when a film thickness of the pixel regulating layer is thinned for that portion, sufficient insulating property can be maintained and a step due to the pixel regulating layer can be reduced. As the result, a film thickness distribution of a layer having an emission function can be more uniformized. Furthermore, short-circuiting of pixels was not caused.

Furthermore, in the first embodiment, a case where an anode is disposed on a glass substrate 100 side is described. However, it goes without saying that first embodiment can be applied as well to a case where a cathode is formed on a glass substrate 100 side.

As detailed above, the first embodiment includes inventions below.

An organic electroluminescent device of the first embodiment is an organic electroluminescent device with a plurality of light emitting portions on a substrate, the light emitting portion including: a pair of electrodes; a light emitting layer interposed between the electrodes; and a transition metal oxide layer disposed between at least one of the electrodes and the light emitting layer, the transition metal oxide layer being formed over the plurality of light emitting portions.

According to the configuration, a transition metal oxide layer is formed integrally over a plurality of pixels. Accordingly, when a transition metal oxide layer is disposed on a lower layer side than a light emitting layer, when the light emitting layer is formed, a high precision light emitting layer can be formed on a flat layer to result in flattening a surface. As the result, when an electrode formed on a top layer of the light emitting layer is patterned as well, a high precision pattern can be obtained.

Furthermore, the transition metal oxide layer is small in the conductivity in a lateral direction; accordingly, even when it is formed integrally over a plurality of pixels, since the crosstalk is hardly generated and the pixel fluctuation is less, high precision emission characteristics can be obtained.

On the other hand, when the transition metal oxide layer is disposed on an upper layer side than the light emitting layer, when an electrode formed on an upper layer side of a pair of electrodes is formed, on a flat surface a high precision pattern can be formed. Furthermore, the transition metal oxide layer can protect a light emitting layer that is a base to inhibit the sputtering damage or the plasma damage from occurring and the plasma damage in the patterning of an electrode can be avoided as well.

Furthermore, according to the configuration, owing to the use of a transition metal oxide as a charge injection layer, an organic electroluminescent device that is very large in the emission intensity and stable in the characteristics can be obtained. This is because, unlike the PEDOT in which a loose bond due to a coulomb interaction of two kinds of polymers tends to come off, even when a current density is increased, without becoming instable, the stable characteristics can be maintained and the emission intensity can be increased. Thus, when a charge injection layer made of a transition metal oxide is disposed integrally on a substrate side over a plurality of pixels, in an organic electroluminescent device, over a wide range of the current density, the emission intensity of the element and the emission efficiency thereof can be maintained at a high level and the lifetime as well can be improved. Accordingly, even when a transition metal oxide layer is disposed on either side of the substrate side or the upper layer side relative to the light emitting layer, the carrier injection characteristics are large and the emission efficiency can be improved.

Still furthermore, the first embodiment includes an organic electroluminescent device where a transition metal oxide layer is formed so as to cover over an electrode formed on a substrate.

Different from a case of an organic film such as a low molecular film that is a high resistor, except for an example where a several nanometers thick thin film made of for instance silicon oxide is used (for instance, a light emitting element that makes use of a tunnel effect in patent literature 5), in the case of a transition metal oxide that has not been considered to integrally form, it was found that the resistance in a transversal direction to a film thickness direction was high and thereby there was no fear of causing the crosstalk between pixels. The invention was achieved considering the foregoing points and when a light emitting layer is formed, even when a patterning process is necessary, since the patterning can be applied while protecting a base and the cross talk can be avoided, while improving the charge injection characteristics, the light emitting layer as well can be integrally formed. Furthermore, since a light emitting layer is formed on a flat layer, without causing the crosstalk, a surface can be flattened. Still furthermore, the oxide used in the invention has a big advantage in that the oxide is substantially transparent in a visible light region and thereby a little dispersion in a film thickness does not cause a large variation on the charge injection characteristics.

The first embodiment includes an organic electroluminescent device where a transition metal oxide layer is formed between an electrode on a side that faces a substrate relative to a light emitting layer and a light emitting layer.

According to the configuration, when an electrode on an upper layer side of the light emitting layer is layered or patterned, the light emitting layer can be protected from damage; accordingly, excellent emission characteristics can be obtained.

Furthermore, the first embodiment includes an organic electroluminescent device that includes a first transition metal oxide layer formed so as to cover over the electrode formed on the substrate and a second transition metal oxide layer formed further integrally on an upper layer of the light emitting layer. That is, the transition metal oxide layer is formed between both electrodes and the light emitting layer.

According to the configuration, the transition metal oxide layer can protect the base layers such as the light emitting layer. Furthermore, when the first transition metal oxide layer is integrally formed, without causing the crosstalk, a surface can be flattened and the light emitting layer can be flattened. Accordingly, the emission characteristics can be uniformized and longer lifetime can be obtained.

The first embodiment includes an organic electroluminescent device in which an effective area of the first electrode formed on the substrate of a pair of electrodes is defined by a pixel restricting layer formed of an insulating film and the transition metal oxide layer is integrally formed so as to cover the pixel restricting layer and an opening disposed by the pixel restricting layer.

According to the configuration, when a first transition metal oxide layer is integrally formed, without causing the crosstalk, a surface can be flattened and thereby the light emitting layer can be flattened. Accordingly, the emission characteristics can be uniformized and longer lifetime can be obtained.

Furthermore, the first embodiment includes an organic electroluminescent device where, in a recess on a surface of a transition metal oxide layer, a light emitting layer is filled.

According to the configuration, a step can be uniformized, a uniform recess can be formed and, the recess, even when it is integrally formed, without causing the crosstalk, can be excellently maintained.

The first embodiment includes an organic electroluminescent device where, in a recess on a surface of a transition metal oxide layer, a plurality of kinds of light emitting layers is filled so as to sequentially arrange.

According to the configuration, on a surface covered by a transition metal oxide layer such as molybdenum oxide, a plurality of kinds of light emitting layers is formed and the step coverage is excellent. Accordingly, a fine step can be avoided, a surface can be flattened and a uniform recess can be formed. Furthermore, the transition metal oxide layer, even when it is integrally formed, without causing the crosstalk, can be maintained excellent.

Furthermore, the first embodiment includes an organic electroluminescent device where a pair of electrodes has a matrix wiring structure and an intersection thereof constitutes a light emitting portion.

The first embodiment includes an organic electroluminescent device where a light emitting layer is interposed between an anode constituted of a reflective material on a substrate and a cathode constituted of a translucent material and a transition metal oxide layer is disposed between the light emitting layer and the anode.

Furthermore, the first embodiment includes an organic electroluminescent device where the transition metal oxide layer contains any one of molybdenum oxide, vanadium oxide and tungsten oxide.

The first embodiment includes a method of producing an organic electroluminescent device with a plurality of light emitting portions, which includes: forming a first electrode on a substrate; forming, as an upper layer of the first electrode, a light emitting layer constituted of an organic semiconductor; and forming a second electrode as an upper layer of the light emitting layer; and, forming a transition metal oxide layer between at least one electrode of the first and second electrodes and the light emitting layer so as to be integrally formed over a plurality of light emitting portions.

Furthermore, the first embodiment includes a method of producing an organic electroluminescent device, where the forming a transition metal oxide layer includes forming so as to cover over an electrode formed on the substrate.

Still furthermore, the first embodiment includes a method of producing an organic electroluminescent device, where the forming a transition metal oxide layer includes forming integrally on an upper layer of the light emitting layer.

Furthermore, the first embodiment includes a method of producing an organic electroluminescent device, where the forming a transition metal oxide layer includes forming a first transition metal oxide layer so as to cover over an electrode formed on the substrate; and forming a second transition metal oxide layer integrally on an upper layer of the light emitting layer, the first and second transition metal oxide layers being disposed on both sides of the light emitting layer.

According to the configuration, the transition metal oxide layer is formed between both electrodes and the light emitting layer. The transition metal oxide layers can protect base layers such as the light emitting layer. Furthermore, when the first transition metal oxide layer is formed integrally, a surface can be flattened and the light emitting layer can be flattened. Accordingly, the emission characteristics can be further improved in the uniformity and further longer lifetime can be realized.

Still furthermore, the first embodiment includes a method of producing an organic electroluminescent device, which includes forming a pixel restricting layer so that an effective area of a first electrode formed on a substrate of the pair of electrodes may be defined by the pixel restricting layer constituted of an insulating film, the transition metal oxide layer being formed integrally so as to cover on the pixel restricting layer.

The first embodiment includes a method of producing an organic electroluminescent device, where the forming a light emitting layer includes filling a light emitting layer in a recess of a surface of the transition metal oxide layer by means of an inkjet method.

The first embodiment includes a method of producing an organic electroluminescent device, where the filling a light emitting material is filling a plurality of kinds of light emitting layers in a recess on a surface of the transition metal oxide layer so as to sequentially arrange.

Furthermore, the first embodiment includes a method of producing an organic electroluminescent device, where the forming the first and second electrodes includes patterning in stripe so that an intersection of matrix wirings forms a light emitting portion.

The first embodiment includes a method of producing an organic electroluminescent device, which further includes: forming a anode with a reflective material on a substrate; forming a transition metal oxide layer between the anode and the light emitting layer; and forming a cathode constituted of a translucent material.

Furthermore, the first embodiment includes a method of producing an organic electroluminescent device, where the forming a transition metal oxide layer includes forming a layer of any one of tungsten oxide, molybdenum oxide and vanadium oxide by a dry process. All transition metal oxide layers formed in the first embodiment contain one constituted of oxides having a plurality of valences (same in embodiments 3 and 4 described below and same in particles of transition metal oxide used in second embodiment). The plurality of valences indicates, for instance in the case of molybdenum oxide, MoO₃, MoO₂ and Mo₂O₃. The charge injection layer 113 (13) or buffer layer 116 (16) is constituted of a mixture of transition metal oxides having a plurality of valences. The mixture can be produced, in the case of, for instance, a vacuum deposition method being used, when, with MoO₃ as a target, an atmosphere in a chamber is made a reducing atmosphere. Similarly, in the case of the sputtering method being used, the mixture can be produced when, with MoO₂ as a sputter target, an oxidizing atmosphere is used to deposit. When the mixture of transition metal oxides having a plurality of valences is used, even when a thickness of the charge injection layer 113 (13) or the buffer layer 116 (16) is thickened, excellent charge injection characteristics can be secured.

Furthermore, the first embodiment includes the organic electroluminescent element of which light emitting layer is constituted of polyfluorene and a derivative thereof expressed by (Ka 1).

Furthermore, the first embodiment includes the organic electroluminescent element where a light emitting layer is constituted of a material having a phenylene vinylene group.

The first embodiment includes the organic electroluminescent element where a light emitting layer is constituted of polyphenylene vinylene and a derivative thereof expressed by (Ka 2).

Furthermore, the first embodiment includes the organic electroluminescent element where a light emitting layer is constituted of at least one kind of a polymer having a dendrimer structure.

The first embodiment includes the organic electroluminescent element where a light emitting layer is constituted of a dendrimer polymer or a dendrimer low molecular structure, which has a light emitting structural unit at a center.

Furthermore, the first embodiment includes an organic electroluminescent device where a function layer includes at least one kind of buffer layer.

The first embodiment includes an organic electroluminescent device where a buffer layer is constituted of a polymer layer.

Furthermore, the first embodiment includes an organic electroluminescent device where a transition metal oxide layer is a charge injection layer containing a molybdenum oxide.

The first embodiment includes an organic electroluminescent device where a transition metal oxide layer is a charge injection layer containing a vanadium oxide.

Furthermore, the first embodiment includes an organic electroluminescent element device where a transition metal oxide layer is a charge injection layer containing a tungsten oxide.

### Second Embodiment

As described in the first embodiment, a typical polymer organic electroluminescent element is prepared by laminating a plurality of functional layers such as a charge injection layer and a light emitting layer between an anode and a cathode. The inventors have proposed that, in place of PEDOT so far used as a charge injection layer, a layer of a transition metal oxide such as molybdenum oxide is used (JP-A No. 2005-203339).

According to an organic electroluminescent element, an organic electroluminescent element improved in the charge injection performance, high in the brightness and long in the lifetime can be obtained. In the organic electroluminescent element, a transition metal oxide layer is formed by means of a dry process such as a vacuum deposition method.

However, in the case of the vacuum deposition method, since an apparatus such as a vacuum unit is necessary, at present a size limit at one-time deposition is substantially 40 cm×40 cm, and an evacuating time, a temperature-up time, a deposition time, a temperature-down time and a time for returning to normal pressure are necessary, these form a bottleneck for shortening a production time.

According to a second embodiment described below, an organic electroluminescent element that can be formed into a large area, can be produced readily and in a short time and is excellent in the production workability can be provided.

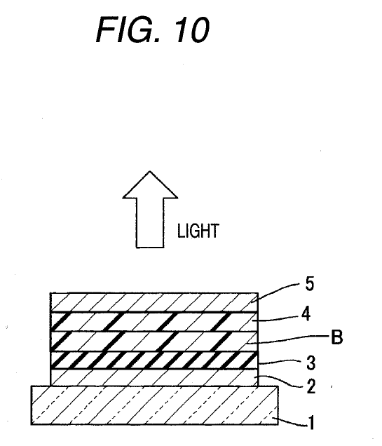

In FIG. 10, a fundamental structure of a polymer organic electroluminescent element of the second embodiment of the invention is shown.

In what follows, a polymer organic electroluminescent element involving the second embodiment will be detailed.

In the second embodiment, with a slurry containing particles of molybdenum oxide that is one of transition metal oxides, by use of a spin coat method, a charge injection layer 3 is formed. That is, as shown in FIG. 10, on an anode 2 made of an aluminum layer formed on a translucent glass substrate 1, a coated film containing molybdenum oxide as a charge injection layer 3, an organic buffer layer B as an electron blocking layer and a polymer material as a light emitting layer 4 are sequentially laminated, followed by sequentially laminating further thereon a barium/aluminum layer as a cathode 5. In the second embodiment, except for the anode 2 and cathode 5, all are formed by means of a coating method such as a spin coat method or a screen print method, and thereby an organic electroluminescent element can be formed on a large area substrate with excellent workability.

Then, for instance, a not shown glass plate and so on are adhered with an adhesive resin so as to cover an entirety of the electroluminescent element to seal. In the second embodiment, a polymer material excellent in the heat resistance is used as the light emitting layer 4 and, as a charge injection layer 3, particles of a transition metal oxide that is a heat resistant inorganic material are used, and thereby the heat resistance of an electroluminescent element per se is improved; accordingly, in the sealing, a thermosetting resin very excellent in the gas barrier properties in comparison with a photo-curable resin can be used.

When, with the anode 2 of the organic electroluminescent element set to a plus electrode and with the cathode 5 set to a minus electrode, a DC current or DC voltage is applied, in the light emitting layer 4 made of a polymer film formed by use of a coating method, holes are injected from the anode 2 through the charge injection layer 3 and electrons are injected from the cathode 5. In the light emitting layer 4, thus injected holes and electrons recombine to generate excitons and, when the excitons return a ground state, a luminescence phenomenon is caused.

According to the organic electroluminescent element of the second embodiment, the charge injection layer 3 is constituted of a coated film containing molybdenum oxide particles; accordingly, without necessitating particular apparatus such as a vacuum unit, a transition metal oxide layer can be formed at high-speed into a large area.

In the next place, an organic electroluminescent device having a structure where polymer organic electroluminescent elements in the second embodiment are arranged in matrix will be described. At the description, FIGS. 1, 2A, 2B and 2C that are used in the description of the first embodiment will be used.

In the second embodiment, with a slurry containing molybdenum oxide particles as an ink, by use of a screen print method, a charge injection layer 13 and a buffer layer 16, which are shown in FIG. 1, are formed. That is, this constitutes a top emission organic electroluminescent element and is produced in such a manner that on an anode 12 made of an aluminum layer formed in stripe as a reflective metal formed on a translucent substrate 11, as a charge injection layer 13, a coated film containing molybdenum oxide is formed so as to form a stripe shape in a direction perpendicular to the striped anode 12, thereon a polymer material layer as an organic buffer layer having the electron blocking function (organic buffer layer B in FIG. 10) and a polymer material as the light emitting layer 14 are sequentially laminated, and further thereon a transition metal oxide (molybdenum oxide) layer as the buffer layer 16 and the cathode 15 are sequentially laminated. An intersection region of the anode 12 and cathode 15 formed in stripe forms a light emitting portion. A reference numeral 17 denotes a partition wall formed of a resist, that is, a trapezoidal protrusion in section as a pixel restricting layer. In the second embodiment, except for the anode 12 and cathode 15, all are formed by use of a coating method such as an inkjet method, screen print method or spin coat method, and thereby, an organic electroluminescent element can be formed on a large area substrate with very excellent workability.

According to the organic electroluminescent element of the second embodiment, the charge injection layer 13 and buffer layer 16 are constituted of a coated film containing molybdenum oxide particles; accordingly, without necessitating particular apparatus such as a vacuum unit, a transition metal oxide layer can be formed into a large area at high speed. Furthermore, in the organic electroluminescent element, an aluminum layer that is a reflective metal is formed on a glass substrate 11 to form an anode 12 and, between the anode 12 and light emitting layer 14 and between the cathode 15 on the upper layer side and the light emitting layer 14, the buffer layer 16 made of a coated film containing molybdenum oxide particles is interposed. Accordingly, a striped pattern that constitutes the anode 12 is flattened by the charge injection layer 13 formed thereon in stripe in a direction perpendicular to the striped pattern and on the top layer thereof the light emitting layer 14 is formed. Then, so as to cover on the light emitting layer 14, the buffer layer 16 constituted of molybdenum oxide particles is formed to further flatten a surface, followed by forming further thereon the cathode 15.

According to the configuration, the light emitting layer 14 is, being formed on the coated layer 16 that contains molybdenum oxide and is integrally formed in stripe over a plurality of light emitting portions (plural pixels), formed on a flattened surface, further through a buffer layer 16 formed integrally on a top layer of the light emitting layer 14 a cathode is formed, and thereby a light emitting layer is constituted so as to have a uniform film thickness. Accordingly, since the electric field concentration can be avoided, an improvement in the emission characteristics and longer lifetime can be achieved.

Furthermore, before the cathode 15 is formed, a surface of the light emitting layer 14 is covered with the buffer layer 16 made of a coated film containing molybdenum oxide particles; accordingly, without damaging the light emitting layer 14, a coating method such as a screen print method can be applied to form and the light emitting layer 14 can be avoided from damaging by sputtering particles during deposition of the cathode 15; accordingly, an excellent surface state can be maintained. According to the configuration, a top emission organic electroluminescent element high in the reliability can be formed. That is, since the buffer layer 16 made of a coated film containing molybdenum oxide particles is formed between the cathode 15 and the light emitting layer 14 excellent electron injection characteristics can be exerted, since the charge injection layer 13 is constituted of a coated film containing molybdenum oxide particles holes can be readily injected and since the organic buffer layer (not shown in the drawing) is disposed on the charge injection layer 13 the punch-through of electrons can be blocked, holes and electrons can effectively contribute to emission within the light emitting layer 14.

In the next place, a process for producing an organic electroluminescent device of the invention will be described.

In the beginning, on a glass substrate 11, by means of the sputtering method, an Al thin film is formed, followed by patterning this by the photolithography to form an anode 12. Then, on a top layer thereof, a resist is coated and, as shown in FIG. 3A, by use of the photolithography, a protrusion having a trapezoidal shape in section is formed as a pixel restricting portion 17. At this time, so as to form a trapezoidal shape in section, an exposure amount in the photolithography is controlled.

Thereafter, as shown in FIG. 3B, on a top layer thereof, by use of the screen print method, a pattern of a coated film containing molybdenum oxide particles is formed to form a charge injection layer 13. As an ink that is used here, a slurry in which a concentration of molybdenum oxide particles of which average particle diameter, the minimum diameter and the maximum diameter, respectively, are controlled so as to be 20 nm, 10 nm and 50 nm may be in the range of 0.1 to 20% is used.

Here, the slurry can be prepared when molybdenum oxide particles are dispersed in a solvent such as water, ethanol, IPA, xylene or toluene. The particle concentration, though not restricted, is in the range of 0.1 to 20%.

Furthermore, when particles are dispersed in a solvent containing a polymer material, a film further improved in the uniformity can be obtained. In this case, when, after a polymer material is dissolved in a solvent, for instance molybdenum oxide particles are added and mixed, a non-aggregated excellent dispersion solution can be obtained. In this case, a concentration of the polymer material is used in the range of 0.1 to 10% and a concentration of particles is generally used in the range of 1 to 100% relative to that of the polymer material without restricting thereto.

Here, examples of the above-mentioned polymer materials include, in addition to MDOPPV, not to mention to so-called conjugate polymers in which a main chain has a continuous repetition structure of a saturated (single) bond between carbon atoms and an unsaturated (double or triple) bond such as poly(p-phenylene vinylene: PPV) and derivatives thereof (poly(2-methoxy-5-dodesiloxy-p-phenylene vinylene), poly(2,5-dioctyloxy-p-phenylene vinylene), poly(2,5-dinonyloxy-p-phenylene vinylene) and poly(2,5-didecyloxy-p-phenylene vinylene); polythiophene and derivatives thereof (poly(3-hexylthiophene), poly(3-heptylthiophene), poly(3-octylthiophene), poly(3-nonylthiophene), poly(3-decylthiophene), poly(3-undecylthiophene), poly(3-dodecylthiophene) and poly(3-(p-dodecylphenylthiophene); polyfluorene and derivatives thereof (poly(9,9-dihexylfluorene, poly(9,9-diheptylfluorene), poly(9,9-dioctylfluorene), poly(9,9-didecylfluorene), poly[9,9-bis(p-hexylphenyl)fluorene, poly[9,9-bis(p-heptylphenyl)fluorene]] and poly[9,9-bis(p-octylphenyl)fluorene]; polyacetylene derivatives (poly(1,2-diphenylacetylene), poly[1-phenyl-2-(p-butylphenyl)acetylene], poly(1-methyl-2-phenylacetylene), poly(1-ethyl-2-phenyl acetylene), poly(1-hexyl-2-phenyl acetylene) and poly(phenylacetylene); polypyridine, poly(pyridyl vinylene), polyphenylene, polyfurane, polyselenophene, poly(phenylene-co-thienylene), poly[1,4-bis(2-thienyl)phenylene], poly(phenyleneethinylene) and derivatives thereof; fluorescent dyes such as tris(8-hydroxyquinoline)aluminum (Alq), coumarin 6 (3-(2-benzothiazolyl)-7(diethylamino)coumarin), coumarin 7 (3-(2-benzoimidazolyl)-7-(diethylamino)coumarin) 4-(dicyanomethylene)-2-methyl-6-(4-dimethylaminostyryl)-4H-pyran (DCM), Nile Red, 1,1,4,4-tetraphenyl-1,3-butadiene), N,N′-dimethylquinacrydone) (DMQA), 1,2,3,4,5-pentaphenylcyclopentadiene (PPCP), N,N′-diphenyl-N,N′-bis(3-methylphenyl)-1,1′-biphenyl-4,4′-diamine (TPD), 2-(4-biphenyl)-5-(4-tert-butylphenyl)-1,3,4-oxydiazole (PBD), p-terphenyl, p-quaterphenyl, 2,2′-bithiophene, 2,2′:5,5′-terthiophene, α-hexathiophene, anthracene, tetracene, phthalocyanine and porphyrin and polymers having a fluorescent dye in a molecular structure; and insulating polymers such as poly(N-vinylcarbazole) (PVK), poly(methylmethacrylate) (PMMA), polycarbonate, polystyrene, poly(methylphenylsilane) and poly(diphenylsilane) containing the foregoing polymers and fluorescent dyes. However, the polymer materials are not restricted thereto.

Furthermore, as the solvents used in the slurry, in addition to IPA, solvents such as water, ethanol, xylene and toluene can be applied.

Thereafter, as shown in FIG. 3C, an organic buffer layer (not shown in the drawing) and a light emitting layer 14, which are made of a polymer, are coated and formed.

Further, thereafter, as shown in FIG. 3D, by use of the screen print method, as a buffer layer 16, a coated film containing molybdenum oxide is formed.

Finally, sputter particles are irradiated by use of the sputtering method to form an ITO thin film as a cathode 15.

Thus, an organic electroluminescent device shown in FIG. 1 can be formed. According to a method of the invention, a charge injection layer 13 and a buffer layer 16 are formed by means of the screen print method; accordingly, the charge injection layer 13 and the buffer layer 16, without necessitating a vacuum unit, can be formed in a large area region at high-speed and with excellent workability. Furthermore, the sputtering damage of the light emitting layer in a process of forming the cathode 15 can be excellently avoided by use of the buffer layer 16 and thereby an excellent surface state can be maintained. Still furthermore, since a polymer material is coated to form the organic buffer layer or the light emitting layer 14, the production is easy and a larger area can be obtained.

Although the charge injection layer 13 is formed by means of the screen print method, it may be formed by means of the spin coat method, followed by patterning by the photolithography. Furthermore, at this time the organic buffer layer and the light emitting layer may be formed by use of the inkjet method. Still furthermore, the ultra-fine oxide particle slurry dispersed in the polymer has to be dried and baked after coating. The process is generally carried out at a temperature in the range of 150 to 200° C. without restricting thereto. Furthermore, before an organic material such as a luminescent material is coated, when the ultra-fine oxide of the second embodiment is used, the polymer used as a binder can be baked at a temperature of 300° C. or more to vaporize and remove.

In the next place, specific examples of the invention will be described.

Since a structure is same as that shown in FIG. 10, FIG. 10 will be referred to describe.

An organic electroluminescent device includes: a 1 mm-thick glass substrate 1 called Corning 7029#; an anode 2 formed on a top layer thereof from an Al thin film having a thickness of 80 nm; a charge injection layer 3 made of a 50 nm-thick coated film containing molybdenum oxide particles formed on a top layer of the anode 2; a light emitting layer 14 formed on the charge injection layer 3 of 80 nm-thick poly[2-methoxy-5-(2-ethylhexyloxy)-1,4-phenylene vinylene] that is a PPV based material; and a 100 nm-thick ITO formed on the light emitting layer 4. Thus prepared sample is taken as sample 301. Although the coated film is formed by use of the spin coat method, other methods such as an inkjet method can be used to form.

In the sample 301, a buffer layer was formed on a charge injection layer 3, followed by similarly forming thereafter (sample 302). As comparison examples, molybdenum oxide (charge injection layer 3) in a sample 301 was replaced with PEDT (sample 303) and molybdenum oxide (charge injection layer) of sample 302 was replaced with PEDT (sample 304) to prepare.

The half brightness lives of the organic electroluminescent devices, respectively, were 70 hr, 100 hr, 10 hr and 20 hr. Here, the half brightness life is obtained by measuring brightness variation under constant current drive with initial brightness set at 1000 Cd.

From the results thereof as well, it is found that when a molybdenum oxide coated film is formed, the lifetime is largely improved.

In the next place, specific examples of the second embodiment will be described.

Since a structure is same as that shown in FIG. 10, FIG. 10 will be referred to describe.

An organic electroluminescent device includes: a 1 mm-thick glass substrate 11 called Corning 7029#; an anode 12 formed on a top layer thereof from an Al thin film having a thickness of 100 nm; a charge injection layer 13 formed on a top layer of the anode 12 of a 50 nm-thick coated film containing molybdenum oxide; poly[9,9-d]octylfluorenyl-2,7-diyl]-alto-co-(N,N′-diphenyl)-N,N′di(p-butyl-oxyphenyl)-1,4-diaminobenzene] as an organic buffer layer that is a 20 nm-thick polyfluorene compound formed on the charge injection layer 13; a light emitting layer 14 made of 80 nm-thick poly[2-methoxy-5-(2-ethylhexyloxy)-1,4-phenylene vinylene] that is a PPV based material; a buffer layer 16 made of a 10 nm-thick coated film containing molybdenum oxide formed on the light emitting layer 14; and a cathode 15 made of a 100 nm-thick indium tin oxide (ITO) layer. Thus prepared sample is taken as a sample 401.

When the screen print was applied, a slurry controlled so that a concentration of molybdenum oxide particles of which average particle diameter, the minimum diameter and the maximum diameter, respectively, are controlled so as to be 20 nm, 10 nm and 50 nm may be in the range of 0.1 to 20% was used.

Thus prepared organic electroluminescent element where molybdenum oxide is used as a charge injection layer is referred to hereinafter as “molybdenum oxide light emitting device”.

Furthermore, as shown in Table 2, one of which charge injection layer 13 was formed of vanadium oxide (sample 402) and one of which charge injection layer 13 was made of tungsten oxide (sample 403) were similarly prepared.

TABLE 2

| 1) | | 2) | | 3) | 4) | 5) | 6) | Cathode | | 7) | 8) | 9) |
|---|---|---|---|---|---|---|---|---|---|---|---|---|
| 401 | 10) | Al (100) | None | MoO₃ | PF | PF | MoO₃ | None | ITO | None | 3000 | 150 |
| | | | | (10) | (20) | (80) | (2) | | (100) | | | |
| 402 | 11) | Al (100) | None | V₂O₅ | PF | PF | V₂O₅ | None | ITO | None | 2600 | 120 |
| | | | | (10) | (20) | (80) | (2) | | (100) | | | |
| 403 | 12) | Al | None | WO₃ | PF | PF | WO₃ | None | ITO | None | 3000 | 150 |
| | | | | (10) | (20) | (80) | (2) | | (100) | | | |
| 404 | 13) | Al (50) | None | PEDT | PF | PF | CuPc | Ba (2) | ITO | Yes | 3200 | 40 |
| | | | | | (20) | (80) | (2) | | (100) | | | |

1) Sample No.
2) Reflective Layer and Anode
3) Hole Injection Layer
4) Organic Buffer Layer
5) Organic Light Emitting Layer
6) Buffer Layer
7) Crosstalk
8) Brightness
9) Half Brightness Life (Hr), @ 5000 Cd
10) Present Invention 1
11) Present Invention 2
12) Present Invention 3
13) Comparative Example

Furthermore, for the sake of comparison, an organic electroluminescent element in which in place of the coated film containing molybdenum oxide of a light emitting device of FIG. 1 a charge injection layer (hole injection layer) formed on the anode 12 was formed with PEDOT and a copper phthalocyanine was formed as a buffer layer between the light emitting layer 14 and the cathode 15 was prepared (comparative example: sample 404).

The organic electroluminescent devices were connected to a DC power source, followed by, while raising a voltage, measuring the emission brightness at 6 V As the result, the molybdenum oxide light emitting device of the sample 401 and the light emitting devices of samples 402 and 403, respectively, without showing the crosstalk, showed substantially 3000 cd/m², 2600 cd/m² and 3000 cd/m² in the emission brightness. On the other hand, the device of comparative example (sample 404) showed such large emission brightness as 3200 cd/m² but was larger in brightness fluctuation. Furthermore, the half brightness life thereof was such short as substantially 40 hr.

In the second embodiment as well, in an organic electroluminescent element, a coated film containing transition metal oxide particles (charge injection layer 13) or the second transition metal oxide layer (buffer layer 16), which is formed between the second electrode (cathode 15) and the light emitting layer 14, is preferably formed so as to cover the light emitting layer 14.

According to the configuration, when a coated film containing a transition metal oxide is formed on the light emitting layer, the light emitting layer can be excellently maintained without receiving damage. Furthermore, when the second electrode is layered or patterned, since the light emitting layer is covered with a transition metal oxide layer, the light emitting layer is protected from the sputter damage or plasma damage, a film high in the reliability can be formed.

Even in the configuration of the second embodiment, it was found that a film thickness of a molybdenum oxide layer formed of particles was very insensitive to the element characteristics. The relationship of the film thickness and element characteristics was described in the first embodiment and omitted from describing here.

Simply putting, in the second embodiment, with same materials as that that constitute the charge injection layer 13 and the buffer layer 16 of the first embodiment, particles are introduced. As to a structure of an organic electroluminescent element and materials selectable for the respective constituent elements, ones described in the first embodiment can be used as these are. Furthermore, applicable applications are same as well. Accordingly, these are omitted from detailing.

As described above, the second embodiment includes inventions below.

In the second embodiment, in an organic electroluminescent element with at least one function layer interposed between a pair of electrodes, the function layer includes a light emitting layer having at least a light emitting function and a layer containing a transition metal oxide disposed between the light emitting layer and at least one of the electrodes.

According to the configuration, since a layer containing a transition metal oxide such as a coated film containing transition metal oxide particles is used, a transition metal oxide-containing film having characteristics substantially same as that of a deposition film can be formed to a large area in one shot; accordingly, without necessitating a large unit, a film high in the reliability can be formed in a short time.

Furthermore, the second embodiment includes the organic electroluminescent element where a layer containing the transition metal oxide is a coated film in which transition metal oxide particles are dispersed in a polymer.

According to the configuration, when a polymer film is used as a light emitting layer, a film structure high in the adhesiveness can be obtained; accordingly, without causing peeling, an organic electroluminescent element high in the reliability can be obtained.

Furthermore, the second embodiment includes the organic electroluminescent element where the coated film is a film in which particles of indium oxide and transition metal oxide are dispersed in a polymer.

According to the configuration, when a polymer film is used as the electroluminescent element and indium oxide or indium tin oxide is used as an electrode, a film structure high in the adhesiveness to the electrode and the light emitting layer can be obtained; accordingly, without causing peeling, an organic electroluminescent element high in the reliability can be obtained.

Still furthermore, the second embodiment includes the organic electroluminescent element that includes, in an organic electroluminescent element having at least one function layer interposed between an anode and a cathode, the function layer that has a light emitting layer having at least a light emitting function and a layer containing a transition metal oxide disposed between the light emitting layer and the anode.

According to the configuration, when a layer such as a coated film containing transition metal oxide particles is disposed on each of both sides of the light emitting layer, without largely deteriorating the workability, the charge injection properties can be further improved. When a film containing a transition metal oxide is formed on a top layer of the light emitting layer, by using such a coating method, at the time of forming a film itself containing a transition metal oxide, the light emitting layer can avoid from being damaged.

The second embodiment includes the organic electroluminescent element in which the anode is an indium tin oxide layer formed on a translucent substrate and the coated film is formed on the indium tin oxide layer.

Furthermore, the second embodiment includes the organic electroluminescent element where all the function layers are constituted of coated films.

According to the configuration, when all function layers are formed of coated films, on a large size substrate, an organic electroluminescent element can be formed at high-speed and with excellent workability. Furthermore, when a flexible substrate is used, while winding a substrate, function layers can be continuously and sequentially formed; accordingly, without necessitating a particular unit, a large area organic electroluminescent element can be formed with excellent workability.

The second embodiment includes an organic electroluminescent device that includes, on a substrate, at least a pair of electrodes and a plurality of light emitting portions that includes at least one function layer and is formed between the electrodes, in which the function layer includes a light emitting layer made of at least one kind of organic semiconductor and a transition metal oxide layer disposed between at least one of the pair of electrodes and the function layer, and the transition metal oxide-containing layer includes a coated film formed continuously over a plurality of light emitting portions.

According to the configuration, since a coated film containing transition metal oxide particles is continuously formed over a plurality of light emitting portions, there is an advantage in that, since there is no need of patterning, the production workability is excellent. Furthermore, it was found that the transition metal oxide layer is high in the resistance in a direction vertical, that is, in a direction transversal to a film thickness direction to be free from fear of the crosstalk. From this, when a light emitting layer is formed, even when a patterning process is necessitated, since the patterning can be applied with a base layer protecting and the crosstalk can be avoided, while improving the charge injection characteristics, the light emitting layer as well can be formed integrally. Furthermore, since the light emitting layer is formed on a flat surface, without causing the crosstalk, a surface can be flattened. Still furthermore, since an oxide used in the invention is substantially transparent in a visible light region, there is a large advantage in that even when a film thickness is a little dispersed the charge injection characteristics are not largely affected.

The second embodiment includes the organic electroluminescent device where the coated film is integrally formed so as to cover on an electrode formed on the substrate.

According to the configuration, with a step generated by an electrode mitigating, the reliability can be improved.

The second embodiment includes the organic electroluminescent device where a layer having the light emitting function is a polymer layer.

According to the configuration, a light emitting layer as well can be formed with a coated film.

The second embodiment includes the organic electroluminescent device where a coated film containing the transition metal oxide is a charge injection layer containing molybdenum oxide.

According to the configuration, the charge injection characteristics can be very much improved.

The second embodiment includes a method of producing an organic electroluminescent element that includes between a pair of electrodes a light emitting layer having at least a light emitting function and between the light emitting layer and at least one of the electrodes a film containing transition metal oxide particles, which includes coating a slurry containing transition metal oxide particles on a substrate on which an electrode is formed to form a coated film and baking the coated film.

According to the configuration, a layer that is high in the reliability and contains a transition metal oxide can be readily formed, without necessitating particular apparatus, into a large area at high-speed.

The second embodiment includes the method of producing an organic electroluminescent element where the baking includes heating at 300° C.

According to the configuration, a binder can be vaporized and a film high in the reliability can be formed.

The second embodiment includes the method of producing an organic electroluminescent element where the forming a coated film includes dispersing transition metal oxide particles and a polymer material in a solvent to prepare a slurry and coating the slurry by means of the spin coat method.

According to the configuration, a film having a flat surface can be very readily formed.

The second embodiment includes the method of producing an organic electroluminescent element where the preparing a slurry includes granulating the transition metal oxide particles so that an average particle diameter thereof may be 20 nm.

According to the configuration, a particle diameter is made small; accordingly, a film excellent in the film quality can be formed. Furthermore, particle diameters of the transition metal oxide particles are desirably granulated so as to be in the range of 10 to 50 nm.

The second embodiment includes the method of producing an organic electroluminescent element where the preparing the slurry includes mixing the transition metal oxide particles together with indium oxide and fine particles to disperse in a solvent.

Furthermore, the second embodiment includes the method of producing an organic electroluminescent element where the forming a film containing a transition metal oxide includes forming a coated film containing transition metal oxide particles on a substrate on which an electrode is formed.

Still furthermore, it goes without saying that the coated film containing transition metal oxide particles includes ones formed by means of, in addition to a spin coat method, an inkjet method, a slit coat method, a screen print method or a gravure print method.

The second embodiment includes a method of producing an organic electroluminescent element that includes between a pair of electrodes a light emitting layer having at least a light emitting function and between the light emitting layer and at least one of the electrodes a layer containing a transition metal oxide, where the forming a layer containing a transition metal oxide includes supplying transition metal oxide particles on the electrode or the light emitting layer to fix.

According to the configuration, with charges supplied on, for instance, an electrode or a light emitting layer, to the charges transition metal oxide particles are adhered owing to a Coulomb force, followed by heating to fix.

### Third Embodiment

As to a top emission organic electroluminescent element described in the first and second embodiments, one in which in a vacuum deposition unit an organic layer and a cathode layer are formed on a glass substrate on which a film of metal such as chromium and silicon oxide are formed is proposed (JP-A No. 2001-43980).

In the organic electroluminescent element described in JP-A No. 43980, as a hole injection layer 4,4′,4″-tris(3-methylphenylphenylamino)triphenyl amine (MTDATA) is used, as a hole transport layer bis(N-naphthyl)-N-phenyl benzidine (α-NPD) is used, as a light emitting layer 8-quinolinol aluminum complex (Alq) is used, as a metal layer of a cathode an alloy of magnesium and silver (Mg:Ag) is used and on a top layer thereof an In—Zn—O based transparent conductive film is formed. The respective materials belonging to organic layers are layered by attaching to predetermined electrodes of a vacuum deposition unit after filling 0.2 g thereof in a resistance heating boat.

In the case of the structure, it is said that, although a top emission organic electroluminescent element can be provided, sufficient emission characteristics are not obtained.

Furthermore, an organic electroluminescent element in which a polymer film is formed as a light emitting layer by use of a coating method is proposed as well. As described in the background art, in a charge injection layer of the organic electroluminescent element, PEDOT is used in many cases.

On the other hand, an organic electroluminescent element is known to show deterioration of the brightness with an accumulated lighting time. Although a reason of deterioration of the emission intensity is variously inferred, the deterioration of PEDOT is considered one of main reasons.

As to such concerns associated with PEDOT, the inventors have proposed to eliminate the PEDOT per se (JP-A No. 2005-203339). However, it has been considered that, in order to inject holes to a light emitting layer, as an anode material a material large in the work function has to be used. Accordingly, when a top emission electroluminescent element is being formed, in actuality, it is considered that there is no way other than that, as an anode material ITO is used and a reflective layer is formed in a lower layer or gold that has the work function same as ITO is used.

The third embodiment includes an organic electroluminescent element with a light emitting layer interposed between an anode and a cathode, in which a transition metal oxide layer is disposed between the light emitting layer and the anode and the anode is constituted of a metal or an alloy smaller in the work function than that of the light emitting layer.

The present inventors have found, after various experiments, that a transition metal oxide such as molybdenum oxide, in an amorphous state, is less in oxygen content than a quantitative ratio, has a plurality of energy levels to have a plurality of conductive paths, has a sufficiently large work function, can form an ohmic contact with a metal and has excellent hole injection characteristics.

So far, it is considered that, on an anode side, only ITO or an electrode material having the work function larger than the ITO can be used. However, when a transition metal oxide such as molybdenum oxide is interposed as a charge injection layer, as an electrode material on the anode side, without considering the magnitude of the work function, a desired material, desirably a reflective metal material can be used, and thereby excellent hole injection characteristics can be obtained. According to the configuration, by use of the transition metal oxide as the charge injection layer, an organic electroluminescent element very large in the emission intensity and stable in the characteristics can be obtained. This is because, unlike PEDOT where a soft bond due to a Coulomb interaction between two kinds of polymer materials tends to come off, without becoming instable even when the current density is increased, stable characteristics can be maintained and the emission intensity can be increased. Thus, when a charge injection layer made of a transition metal oxide is disposed on a substrate side, in a top emission organic electroluminescent element, over a wide range of the current density, the emission intensity and emission efficiency of an element can be maintained at a high level and the life can be improved. Accordingly, an organic electroluminescent element that can be stably operated in a wide brightness range up to high brightness and is excellent in the lifetime characteristics can be realized.

In what follows, an organic electroluminescent element involving the third embodiment will be described. In the beginning, a configuration thereof will be described with reference to FIG. 10.

In the third embodiment, on an anode 2 made of an aluminum layer as a reflective metal formed on a translucent glass substrate 1, as a charge injection layer 3 a molybdenum oxide thin film is formed, thereon a polymer layer as an organic buffer layer B having an electron blocking function and a polymer as a light emitting layer 4 are sequentially laminated, and further thereon a translucent cathode 5 constituted of indium tin oxide (ITO) is formed.

According to an organic electroluminescent element of the third embodiment, an aluminum layer that is a reflective metal is formed on a glass substrate 1 as an anode 2 to form a top emission organic electroluminescent element. Since a charge injection layer 3 is made of a molybdenum oxide thin film, holes can be easily injected, and since the electron punch-through can be blocked with an organic buffer layer B, electrons can effectively contribute to emission in a layer having the emitting function. Accordingly, excellent emission characteristics can be obtained and even under high temperatures an element high in the reliability can be obtained.

As mentioned above, aluminum used as an anode 2 in the third embodiment, which is low in the resistance and excellent in the workability and has the reflectivity, can be formed in the same process as that of in particular a wiring pattern at the integration, is a very effective material. However, since its work function is such small as substantially 4.20 eV, the aluminum has been considered incapable of applying as an anode 2 in an existing organic electroluminescent element. However, as the result of various experiments, it was found that when a layer of a transition metal oxide such as molybdenum oxide was used as a charge injection layer 3, excellent emission characteristics could be obtained and thereby a top emission organic electroluminescent element could be formed. According to the configuration, since a layer of aluminum or aluminum alloy that is reflective and low in the resistance can be used as an anode 2, an organic electroluminescent element excellent in the emission characteristics can be formed.

Furthermore, as shown in specific examples described below, in an anode 2, silver or a silver alloy can be used as well.

Silver that is low in the resistance, can be formed as a coated film and has the reflectivity can be formed in the same process as that of in particular a wiring pattern at the integration; accordingly, it is a very effective material. However, since its work function is such small as substantially 4.73 eV, silver is not used as an anode 2 in an existing organic electroluminescent element. However, when a layer of a transition metal oxide such as molybdenum oxide is used as a charge injection layer 3, similarly to the aluminum, excellent emission characteristics can be obtained.

Still furthermore, in an anode 2, copper or a copper alloy can be used as well.

Copper that is low in the resistance, can be formed as a coated film and has the reflectivity can be formed in the same process as that of in particular a wiring pattern at the integration; accordingly, it is a very effective material. However, since its work function is such small as substantially 4.1 to 4.5 eV, copper is not used as an anode in an existing organic electroluminescent element. However, similarly to the aluminum and silver, when a layer of a transition metal oxide such as molybdenum oxide is used as a charge injection layer 3, excellent emission characteristics can be obtained.

Thus, when, as a top layer of an anode 2 (between the anode 2 and the light emitting layer 4), a layer of a transition metal oxide such as molybdenum oxide is disposed, a width of selection of materials that constitute the anode 2 can be expanded. Furthermore, these may be disposed between the cathode 5 and the light emitting layer 4. In the case as well, a width of selection of materials that constitute the cathode 5 can be expanded.

In the next place, a process of producing an organic electroluminescent element of the third embodiment will be described.

In the beginning, on a glass substrate 1, an Al thin film is formed by use of the sputtering method, followed by forming a molybdenum oxide thin film by use of the vapor deposition method, further followed by patterning by use of the photolithography to form an anode 2 and a charge injection layer 3.

Thereafter, by means of the coating method, an organic buffer layer B and a light emitting layer 4, which are made of a polymer material, are coated and formed.

At the last, a cathode 5 is formed.

Thus, an organic electroluminescent element shown in FIG. 10 is formed. According to the method, since a polymer material is coated to form an organic buffer layer B and a light emitting layer 4, the production is easy and an area can be increased.

Subsequently, specific examples of the third embodiment will be described.

Since a structure is same as that shown in FIG. 10, FIG. 10 will be referred to describe.

An organic electroluminescent element includes: a 1 mm-thick glass substrate 1 called Corning 7029#; an anode 2 formed on a top layer thereof from an Al thin film having a thickness of 100 nm; a charge injection layer 3 formed on a top layer of the anode 2 of a 50 nm-thick molybdenum oxide thin film; poly[(9,9-dioctylfluorenyl-2,7-diyl)-alto-co-(N,N′-diphenyl)-N,N′di(p-butyl-oxyphenyl)-1,4-diaminobenzene]] as an organic buffer layer B that is a 20 nm-thick polyfluorene compound formed on the charge injection layer 3; a light emitting layer 4 made of 80 nm-thick poly[2-methoxy-5-(2-ethylhexyloxy)-1,4-phenylene vinylene] that is a PPV based material; and a cathode 5 formed on the light emitting layer 4 from a 2 nm-thick barium (Ba) layer, a 2 nm-thick aluminum (Al) layer and a 100 nm-thick indium tin oxide (ITO) layer. Thus prepared sample is taken as a sample 601.

Thus prepared organic electroluminescent element where molybdenum oxide is used as a charge injection layer 3 is referred to hereinafter as “molybdenum oxide element”.

Furthermore, as shown in Table 3, one of which anode material is changed to a silver thin film in place of an aluminum thin film (sample 602) and one of which anode material is changed to chromium (sample 603) were similarly prepared.

TABLE 3

| 1) | | 2) | | 3) | 4) | 5) | Cathode | | | 6) | 7) |
|---|---|---|---|---|---|---|---|---|---|---|---|
| 601 | 8) | Al (100) | | MoO₃ | PF | PF (80) | Ba (2) | Al (2) | ITO | 3400 | 0 |
| | | | | (50) | (20) | | | | (100) | | |
| 602 | 9) | Ag (100) | | MoO₃ | PF | PF (80) | Ba (2) | Al (2) | ITO | 3500 | 0 |
| | | | | (50) | (20) | | | | (100) | | |
| 603 | 10) | Cr (100) | | MoO₃ | PF | PF (80) | Ba (2) | Al (2) | ITO | 3400 | 0 |
| | | | | (50) | (20) | | | | (100) | | |
| 701 | 11) | Al (100) | | None | PF | PF (80) | Ba (2) | Al (2) | ITO | 450 | 0 |
| | | | | | (20) | | | | (100) | | |
| 702 | 12) | Ag (100) | | None | PF | PF (80) | Ba (2) | Al (2) | ITO | 450 | 0 |
| | | | | | (20) | | | | (100) | | |
| 703 | 13) | Al (100) | ITO | None | PF | PF (80) | Ba (2) | Al (2) | ITO | 1600 | 5 |
| | | | (100) | | (20) | | | | (100) | | |
| 704 | 14) | Ag (100) | ITO | None | PF | PF (80) | Ba (2) | Al (2) | ITO | 1200 | 7 |
| | | | (100) | | (20) | | | | (100) | | |
| 705 | 15) | Ag (100) | ITO | None | PF | PF (80) | Ba (2) | Al (2) | ITO | 1200 | 7 |
| | | | (100) | | (20) | | | | (100) | | |
| 706 | 16) | Ag (100) | None | PEDT | PF | PF (80) | Ba (2) | Al (2) | ITO | 900 | 0 |
| | | | | | (20) | | | | (100) | | |

1) Sample No.
2) Reflective Layer and Anode, ( ): thickness (nm)
3) Hole Injection Layer
4) Organic Buffer Layer
5) Organic Luminescent Layer
6) Brightness (at 6 V)
7) Number of Short-circuited Elements of 10 Elements
8) Present Invention 1
9) Present Invention 2
10) Present Invention 3
11) Comparative Example 1
12) Comparative Example 2
13) Comparative Example 3
14) Comparative Example 4
15) Comparative Example 5
16) Comparative Example 6

In the element shown in FIG. 10, the charge injection layer 3 was not provided and a configuration on the anode 2 side was changed, and thereby elements (samples 701 through 705) were prepared as comparative examples 1 through 5. Furthermore, an element where the charge injection layer 3 was changed to 70 nm-thick PEDOT: PSS (sample 706) was prepared as comparative example 6.

The elements were connected to a DC power source, followed by raising a voltage to measure the emission brightness at 6 V As the result, the molybdenum oxide elements of samples 601 through 603 showed the brightness of substantially 3400 to 3500 Cd/m². On the other hand, samples 701 through 706 as the comparative example showed greatly reduced brightness in the range of substantially 450 to 1200 Cd/m². Furthermore, the respective samples were prepared by 10 pieces and the number of short-circuited elements was evaluated. Samples 601 through 603 did not show the short-circuiting.

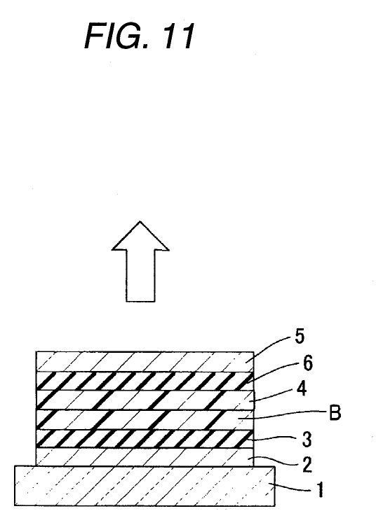

FIG. 11 is a sectional view showing an essential portion of a modified example of an organic electroluminescent element of the third embodiment of the invention.

A different point between the organic electroluminescent element shown in FIG. 11 and the organic electroluminescent element of the third embodiment is in that, in the modified example, on a cathode 5 side of the light emitting layer 4, as a buffer layer 6, a molybdenum oxide thin film is formed. Other configurations are same as that of FIG. 10 referred to in the third embodiment.

According to the configuration, the brightness was further increased and the half brightness life as well was improved.

As shown in Table 4, on a cathode 5 side, a 2 nm-thick molybdenum oxide layer is formed as the buffer layer 6.

According to the configuration, as shown in Table 4 as sample 801, the brightness was further improved to 4900 Cd/m² that is more than that of samples 601 through 603.

TABLE 4

| 1) | | 2) | | 3) | 4) | 5) | 6) | Cathode | | 7) | 8) |
|---|---|---|---|---|---|---|---|---|---|---|---|
| 801 | 9) | Al (100) | None | MoO₃ | PF | PF | MoO₃ | None | ITO | 4900 | 200 |
| | | | | (10) | (20) | (80) | (2) | (100) | | | |
| 902 | 10) | Al (50) | None | PEDT | PF | PF | CuPc | Ba (2) | ITO | 3200 | 80 |
| | | | | | (20) | (80) | (2) | (100) | | | |

1) Sample No.
2) Reflective Layer and Anode
3) Hole Injection Layer
4) Organic Buffer Layer
5) Organic Luminescent Layer
6) Buffer Layer
7) Brightness
8) Half Brightness Life (Hr), @ 10000 Cd
9) Present Invention
10) Comparative Example

Thus, when, not only on the anode 2 side but also on the cathode 5 side, a molybdenum oxide layer as a buffer layer 6 is interposed, since molybdenum oxide forms an ohmic contact with the light emitting layer 4, without depending on the work functions of electrode materials that form the anode 2 and the cathode 5, the hole and electron injection characteristics can be improved.

For the sake of comparison, when a charge injection layer (hole injection layer) formed on the anode 2 was formed from PEDOT and between the light emitting layer 4 and the cathode 5 copper phthalocyanine was formed as a buffer layer (sample 801), not only the brightness was lowered to 3200 Cd/m² but also the half brightness life was reduced from 200 hr to 80 hr, that is, less than one half.

In the organic electroluminescent element described in the third embodiment, as the structure thereof and materials selectable for the respective constituents, ones same as that described in the first embodiment can be used as they are. Furthermore, applicable applications are same as well. Accordingly, these will be omitted from describing.

Furthermore, a configuration of the second embodiment is introduced in a mode described in the third embodiment, that is, a transition metal oxide layer may be formed of particles and can be formed by use of a so-called coating method.

As detailed above, the third embodiment includes inventions below.

The third embodiment includes an organic electroluminescent element having a light emitting layer interposed between an anode and a cathode, in which between the anode and cathode a transition metal oxide layer is disposed and the anode is constituted of a metal or an alloy smaller in the work function than that of the light emitting layer.

Furthermore, the third embodiment includes the organic electroluminescent element in which an anode is constituted of a reflective metal or metal alloy and a cathode is constituted of a translucent material.

Still furthermore, the third embodiment includes the organic electroluminescent element in which the anode is made of an aluminum or aluminum alloy layer formed on a translucent substrate.

The third embodiment includes the organic electroluminescent element in which the anode is made of a silver or silver alloy layer formed on a translucent substrate.

Furthermore, the third embodiment includes the organic electroluminescent element in which the anode is made of a copper or copper ally layer formed on a translucent substrate.

Still furthermore, the third embodiment includes the organic electroluminescent element in which the light emitting layer is constituted of polyfluorene and a derivative thereof expressed by (ka 1) described in the first embodiment.

The third embodiment includes the organic electroluminescent element in which the light emitting layer is constituted of a material having a phenylene vinylene group.

Furthermore, the third embodiment includes the organic electroluminescent element in which the light emitting layer is constituted of polyphenylene vinylene and a derivative thereof expressed by (Ka 2) described in the first embodiment.

Still furthermore, the third embodiment includes the organic electroluminescent element in which the light emitting layer is constituted of at least one kind of polymer material having a dendrimer structure.

The third embodiment includes the organic electroluminescent element in which the light emitting layer is constituted of a dendrimer polymer or a dendrimer low molecular structure having a light emitting structural unit at a center.

Furthermore, the third embodiment includes the organic electroluminescent element that includes at least one kind of buffer layer between the anode and the light emitting layer.

Still furthermore, the third embodiment includes the organic electroluminescent element in which the buffer layer is constituted of a polymer layer.

The third embodiment includes the organic electroluminescent element in which the transition metal oxide layer is a charge injection layer containing molybdenum oxide.

Furthermore, the third embodiment includes the organic electroluminescent element in which the transition metal oxide layer is a charge injection layer containing vanadium oxide.

Still furthermore, the third embodiment includes the organic electroluminescent element in which the transition metal oxide layer is a charge injection layer containing tungsten oxide.

The third embodiment includes the organic electroluminescent element in which the charge injection layer is constituted of a hole injection layer formed on the anode and an electron injection layer formed on the light emitting layer so as to face the hole injection layer through the light emitting layer, and both the hole injection layer and the electron injection layer are constituted of a transition metal oxide layer.

Furthermore, the third embodiment includes the organic electroluminescent element in which the anode is formed on a substrate divided into a plurality of parts and the transition metal oxide layer constitutes a hole injection layer formed so as to cover integrally the plurality of anodes.

Although a transition metal oxide such as molybdenum oxide forms an ohmic contact with metal, since it is highly resistant, the crosstalk is not caused even when these are integrally formed. A reason for this is considered in that the resistance of molybdenum oxide between pixels is very high. However, a detailed reason is not clear.

Still furthermore, the third embodiment includes the organic electroluminescent element in which the light emitting layer is laminated on the hole injection layer.

In the case of a unicolor organic electroluminescent element, a light emitting layer may well be formed so as to cover an entire surface of a hole injection layer. Furthermore, when a light emitting layer is necessarily formed divided like in a color organic electroluminescent layer, a patterning process of a light emitting layer or a frame layer that separates the light emitting layer becomes necessary. However, since a hole injection layer made of a transition metal oxide such as molybdenum oxide is present as a base, an anode surface can avoid damage; accordingly, an organic electroluminescent element excellent in the light emitting characteristics can be provided.

The third embodiment includes, in the organic electroluminescent element, on an anode at least a surface of which is constituted of a metal material having the work function smaller than that of a light emitting layer, forming a transition metal oxide layer, forming a light emitting layer on the transition metal oxide layer and forming a cathode.

Desirably, as the anode, a reflective metal material is used.

Furthermore, the third embodiment includes the method of producing an organic electroluminescent element, in which the forming the transition metal oxide layer is forming a molybdenum oxide layer by use of a dry process.

Still furthermore, the third embodiment includes the method of producing an organic electroluminescent element, in which the forming the transition metal oxide layer is forming a tungsten oxide layer by use of a dry process.

The third embodiment includes the method of producing an organic electroluminescent element, in which the forming a transition metal oxide layer is forming a vanadium oxide layer by use of a dry process.

To be reflective here, though indicating one that substantially reflects light, includes one that partially transmits light. For instance, when a film thickness of an aluminum film is controlled so as to partially transmit light, an amount of transmitted light can be measured by a photosensor disposed behind that. Furthermore, in a case where light is partially scattered by irregularities on an anode surface, when reflected light is substantially utilized, it is also contained in the invention.

### Fourth Embodiment

As described in the first embodiment and so on as well, a polymer organic electroluminescent element is advantageous in that it can be produced by use of a simple process.

However, in the case of a top emission organic electroluminescent element, there is a problem in that, in the sputtering process necessary for forming a transparent conductive film formed on a top layer of a light emitting layer, sputtering particles damage a function layer such as a light emitting layer.

In order to avoid the problem, there is proposed an electroluminescent element in which an upper electrode is formed of a first conductive layer formed by the deposition method and a second conductive layer formed by the sputtering method and therebetween a buffer layer is interposed to inhibit the sputter damage (JP-A No. 9-63928).

However, in the method, the first conductive layer has to be patterned. When the first conductive layer is patterned, since an organic layer (light emitting layer) that is a base is exposed to an etchant such as gas plasma, the damage cannot be avoided. That is, the problem is not completely resolved.

Accordingly, there is a problem in that sufficiently large emission intensity cannot be obtained. Furthermore, there is a problem as well in that, when an element is operated for a long term, the life is not sufficient.

In what follows, an organic electroluminescent element involving the fourth embodiment will be described. In the beginning, a structure will be described with reference to FIG. 10.

The fourth embodiment constitutes a top emission organic electroluminescent element and the organic electroluminescent element is produced in such a manner that, on an anode 2 made of an aluminum layer as a reflective metal formed of a translucent glass substrate 1, a molybdenum oxide thin film is formed as a charge injection layer 3, thereon a polymer layer as an organic buffer layer B having an electron blocking function and a polymer as a light emitting layer 4 are sequentially laminated, and, further thereon, a transition metal oxide (molybdenum oxide) layer as a buffer layer 6 and a cathode 5 are sequentially laminated.

According to the organic electroluminescent element of the fourth embodiment, a layer of aluminum that is a reflective metal material is formed on a glass substrate 1 as an anode 2 and between the cathode 5 on an upper layer side and the light emitting layer 4 a buffer layer 6 made of a molybdenum oxide thin film is interposed. Accordingly, before the cathode 5 is formed, a surface of the light emitting layer 4 is covered with the buffer layer 6 made of a molybdenum oxide thin film. As the result, since sputtering particles are inhibited from damaging at the deposition, an excellent surface state can be maintained. According to the configuration, a top emission organic electroluminescent element high in the reliability can be constituted, since the buffer layer 6 made of a molybdenum oxide thin film is formed between a cathode and a light emitting layer excellent charge injection characteristics can be exerted, since the charge injection layer 3 is constituted of a molybdenum oxide thin film holes can be readily injected, the organic buffer layer B can block the punch-through of electrons, and holes and electrons can effectively contribute to emission in a layer having a light emitting function. Accordingly, excellent emission characteristics can be obtained and even under high temperatures an element high in the reliability can be obtained.

Furthermore, when, on a base, a driving thin film transistor is formed or a photo-detecting thin film transistor is formed as well, emission of the organic electroluminescent element, without being disturbed, can be excellently extracted outside thereof.

In the next place, a process of producing an organic electroluminescent element of the invention will be described.

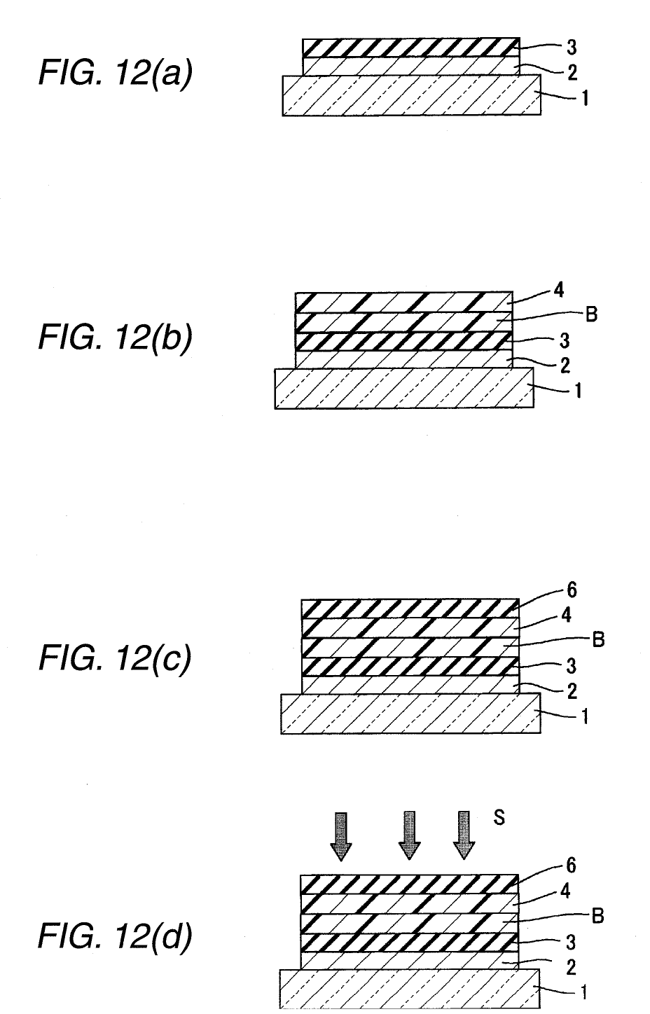

In the beginning, as shown in FIG. 12A, on a glass substrate 1, an Al thin film is formed by use of the sputtering method, followed by forming a molybdenum oxide thin film by use of the vapor deposition method, further followed by patterning these by use of the photolithography to form an anode 2 and a charge injection layer 3.

Thereafter, by means of the coating method, as shown in FIG. 12B, an organic buffer layer B and a light emitting layer 4, which are made of a polymer material, are coated to form.

Further thereafter, as shown in FIG. 12C, a molybdenum oxide thin film is formed as a buffer layer 6.

At the last, as a state at the deposition is shown in FIG. 12D, sputtering particles S are sputtered by means of the sputtering method to form an ITO thin film as a cathode 5 (since FIG. 12D assumes a state during the deposition, a cathode 5 is not shown in the drawing).

Thus, an organic electroluminescent element shown in FIG. 10 is formed. According to the method shown in the fourth embodiment, since the buffer layer 6 can excellently inhibit the light emitting layer 4 from being sputter damaged during the forming a cathode 5, an excellent surface state can be maintained. Furthermore, the organic buffer layer B and the light emitting layer 4 are formed by coating a polymer material; accordingly, the production is easy and an area can be increased.

Subsequently, a specific example of the fourth embodiment will be described.

Since a structure is same as that shown in FIG. 10, FIG. 10 will be referred to describe.

An organic electroluminescent element includes: a 1 mm-thick glass substrate 1 called Corning 7029#; an anode 2 formed on a top layer thereof from an Al thin film having a thickness of 100 nm; a charge injection layer 3 formed on a top layer of the anode 2 from a 50 nm-thick molybdenum oxide thin film; poly[9,9-dioctylfluorenyl-2,7-diyl]-alto-co-(N,N′-diphenyl)-N,N′di(p-butyl-oxyphenyl)-1,4-diaminobenzene] as an organic buffer layer B that is a 20 nm-thick polyfluorene compound formed on the charge injection layer 3; a light emitting layer 4 made of 80 nm-thick poly[2-methoxy-5-(2-ethylhexyloxy)-1,4-phenylene vinylene] that is a PPV based material; a buffer layer 6 made of a 2 nm-thick molybdenum oxide thin film formed on the light emitting layer 4; and a cathode 5 made of a 100 nm-thick indium tin oxide (ITO) layer. Thus prepared sample is taken as a sample 1001.

Thus prepared organic electroluminescent element where molybdenum oxide is used as a charge injection layer 3 is hereinafter referred to as “molybdenum oxide element”.

Furthermore, as shown in Table 5, one in which a material of a cathode 5 is changed from the ITO to a 2 nm-thick barium (Ba) layer and a 2 nm-thick aluminum (Al) layer (sample 1002) and one in which a material of the cathode 5 is changed from the ITO to a laminate structure of a 2 nm-thick barium (Ba) layer, a 2 nm-thick aluminum (Al) layer and a 100 nm-thick indium tin oxide (ITO) layer (sample 1003) were similarly prepared.

TABLE 5

| 1) | | 2) | | 3) | 4) | 5) | 6) | Cathode | | | 7) | 8) |
|---|---|---|---|---|---|---|---|---|---|---|---|---|
| 1001 | 9) | Al (100) | None | MoO₃ | PF | PF | MoO₃ | None | ITO | | 4900 | 200 |
| | | | | (10) | (20) | (80) | (2) | | (100) | | | |
| 1002 | 10) | Al (100) | None | MoO₃ | PF | PF | MoO₃ | Ba (2) | Au | | 2800 | 110 |
| | | | | (10) | (20) | (80) | (2) | | (10) | | | |
| 1003 | 11) | Al (100) | None | MoO₃ | PF | PF | MoO₃ | Ba (2) | Al (2) | ITO | 3800 | 140 |
| | | | | (10) | (20) | (80) | (2) | | | (100) | | |
| 1101 | 12) | Al (50) | None | MoO₃ | PF | PF | None | None | ITO | | 16) | — |
| | | | | (10) | (20) | (80) | | | (100) | | | |
| 1102 | 13) | Al (50) | None | MoO₃ | PF | PF | None | Ba (2) | Au | | 2000 | 60 |
| | | | | (10) | (20) | (80) | | | (10) | | | |
| 1103 | 14) | Al (50) | None | MoO₃ | PF | PF | None | Ba (2) | Al (2) | ITO | 4200 | 65 |
| | | | | (10) | (20) | (80) | | | | (100) | | |
| 1104 | 15) | Al (50) | None | PEDT | PF | PF | CuPc | Ba (2) | ITO | | 3200 | 80 |
| | | | | | (20) | (80) | (2) | | (100) | | | |

1) Sample No.
2) Reflective Layer and Anode
3) Hole Injection Layer
4) Organic Buffer Layer
5) Organic Luminescent Layer
6) Buffer Layer
7) Brightness
8) Half Brightness Life, (Hr), @ 10000 Cd
9) Present Invention 1
10) Present Invention 2
11) Present Invention 3
12) Comparative Example 1
13) Comparative Example 2
14) Comparative Example 3
15) Comparative Example 4
16) Large Irregularity

Furthermore, in the element shown in FIG. 10, the charge injection layer 3 was eliminated to prepare elements (samples 1101 through 1103) as comparative examples 1 through 3. Still furthermore, for the sake of comparison, a sample 1104 in which the charge injection layer (hole injection layer) formed on the anode 2 was formed with PEDOT and copper phthalocyanine was disposed as a buffer layer between the light emitting layer 4 and the cathode 5 was formed.

The elements were connected to a DC power source, followed by raising a voltage to measure the emission brightness at 6 V As the result, the molybdenum oxide elements of samples 1101 through 1103, respectively, showed the brightness of substantially 4900, 2800 and 3800 cd/m². On the other hand, elements of comparative examples showed large brightness irregularity (sample 1101) or reduced brightness such as 2000 cd/m² (sample 1102). Furthermore, it was found that even in one that is such large in the brightness as 4200 cd/m² like comparative example 3 (sample 1103), the half brightness life was such short as substantially 65 hr.

Still furthermore, in the sample 1104 in which PEDOT was used, although the brightness was 3200 Cd/m², the half brightness life was lowered from 200 hr to 80 hr, that is, less than half.

So far, when ITO that constitutes a cathode 5 is formed by use of the sputtering method, a light emitting layer cannot avoid from being sputter damaged. However, as mentioned above, when a molybdenum oxide layer is interposed on a side of the cathode 5 as well, since the sputtering damage can be avoided, a surface state of the light emitting layer 4 can be maintained excellent and molybdenum oxide forms an ohmic contact with the light emitting layer 4, without depending on the work function of an electrode material that constitutes the cathode 5, the electron injection characteristics can be improved and the hole blocking properties can be improved.

In particular, in the organic electroluminescent element, a transition metal oxide layer (buffer layer 6) formed between a second electrode (electrode on a light exit side, which corresponds to a cathode 5 in the configuration shown in FIG. 10) and a light emitting layer 4 or a transition metal oxide layer as a charge injection layer 3 is desirably formed so as to cover the light emitting layer 4. That is, in FIG. 10, these are depicted same in size in a transversal direction; however, the charge injection layer 3 and the buffer layer 6 are preferably formed larger than a formation range of the light emitting layer 4.

According to the configuration, when the second electrode (cathode 5 that is an electrode on an upper layer) is deposited or the second electrode is patterned, since the light emitting layer 4 is covered with a transition metal oxide layer, the light emitting layer 4 is protected from the sputter damage or plasma damage, thereby a film high in the reliability can be formed.

In the electroluminescent element described in the fourth embodiment, the structure thereof and materials selectable for the respective constituents may be same as that described in the first embodiment. Furthermore, applicable applications as well are same. Accordingly, detailed descriptions thereof will be omitted.

Furthermore, a configuration of the second embodiment may be introduced in a mode described in the fourth embodiment, that is, a transition metal oxide layer may be constituted of particles and this may be formed by use of the so-called coating method.

As detailed above, the fourth embodiment includes inventions below.

The fourth embodiment is an organic electroluminescent element provided with, a first electrode formed on a substrate, a second electrode and a light emitting layer disposed between the first and second electrodes, in which a transition metal oxide layer is formed between the light emitting layer and the second electrode and light is extracted from the second electrode side.

According to the configuration, since a transition metal oxide layer is formed on the light emitting layer, even when, at the formation of the second electrode, the sputtering or plasma is used to deposit or etching is applied to pattern, the light emitting layer that is a base is not damaged; accordingly, the light emitting layer can maintain an excellent surface state to heighten the reliability.

The fourth embodiment is an organic electroluminescent element provided with a first electrode formed on a substrate, a second electrode and a light emitting layer disposed between the first and second electrodes, in which a first transition metal oxide layer is formed between the light emitting layer and the first electrode, a second transition metal oxide layer is formed between the light emitting layer and the second electrode and light is extracted from the second electrode side.

According to the configuration, in addition to the foregoing advantages, since a transition metal oxide layer is disposed between both of the first and second electrodes and the light emitting layer, irrespective of what materials being used in the first and second electrodes, both in production and use, without causing the migration, the light emitting layer can be assuredly protected.

The fourth embodiment includes the organic electroluminescent element in which second electrode is a thin film formed by use of a dry process.

In particular, when a dry process such as the sputtering, plasma CVD or vacuum vapor deposition is used, the sputtering particles or plasma tend to damage. However, since the light emitting layer is covered with a transition metal oxide layer and the transition metal oxide layer protects the light emitting layer, an excellent surface state can be maintained. The light emitting layer can be protected, without restricting to the deposition, as well when the etching process in the patterning is a dry process such as the sputtering or the plasma etching.

The fourth embodiment includes the organic electroluminescent element in which a first electrode is an anode constituted of a reflective metal or metal alloy material and a second electrode is a translucent cathode.

Furthermore, the fourth embodiment includes the organic electroluminescent element in which the second electrode is a metal or metal compound thin film formed by use of the sputtering method.

Still furthermore, the fourth embodiment includes the organic electroluminescent element in which the second electrode is constituted of an indium tin oxide (ITO) thin film or an indium zinc oxide (IZO) thin film.

The fourth embodiment includes the organic electroluminescent element in which a transition metal oxide layer or second transition metal oxide layer formed between the second electrode and the light emitting layer is formed so as to cover the light emitting layer.

According to the configuration, when the second electrode is deposited or the second electrode is patterned, since the light emitting layer is covered with a transition metal oxide layer, the light emitting layer is protected from the sputter damage or plasma damage and thereby a film high in the reliability can be formed.

Furthermore, the fourth embodiment includes a method of producing an organic electroluminescent element, which includes forming a first electrode of a pair of electrodes on a substrate; forming a light emitting layer; forming a transition metal oxide layer; and forming, after forming a transition metal oxide layer, a translucent second electrode, a dry process being used to form the second electrode.

According to the configuration, since a transition metal oxide layer is formed on the light emitting layer, at the formation of the second electrode, even when a dry process such as the sputtering or plasma is used to deposit or the etching is used to pattern, the light emitting layer that is a base is not damaged.

The fourth embodiment includes the method of producing an organic electroluminescent element in which a first electrode is an anode constituted of a reflective metal or metal alloy and a second electrode is a cathode.

Furthermore, the fourth embodiment includes the method of producing an organic electroluminescent element, in which forming a second electrode includes depositing a metal or metal compound thin film by means of the sputtering method.

According to the configuration, since the transition metal oxide layer is disposed on the light emitting layer, at the formation of the second electrode, even when the sputtering is used to form a metal or metal compound thin film, the light emitting layer that is a base is not damaged.

The fourth embodiment includes the method of producing an organic electroluminescent element, in which the forming a second electrode includes forming an indium tin oxide (ITO) thin film or an indium zinc oxide (IZO) thin film by means of the sputtering method.

In particular, in the forming an indium tin oxide (ITO) thin film or an indium zinc oxide (IZO) thin film, the base tends to be damaged. However, since the base is covered with a transition metal oxide layer, the light emitting layer present as the base is not damaged.

Furthermore, the fourth embodiment includes the method of producing an organic electroluminescent element, which includes, prior to forming the light emitting layer, forming a transition metal oxide layer on the first electrode, and the forming a second electrode includes forming a cathode constituted of a metal smaller in the work function than that of the light emitting layer.

Still furthermore, the fourth embodiment includes the method of producing an organic electroluminescent element, in which the forming a second electrode includes depositing a metal thin film by use of the vacuum deposition method and patterning the metal thin film.

According to the configuration, due to the presence of a transition metal oxide layer that covers the light emitting layer, the light emitting layer is protected from the process damage such as the plasma damage in the patterning a metal thin film; accordingly, stable characteristics can be maintained.

Here, a substrate may be a translucent substrate or a light-shielding substrate. However, in the case of the translucent substrate, although it is necessary to give the reflectiveness only by an anode, since a transition metal oxide layer is used as a charge injection layer, without considering the work function of a material as described in the third embodiment, a material high in the reflectiveness can be used.

Furthermore, the fourth embodiment includes the method of producing an organic electroluminescent element of which light emitting layer is a polymer layer.

Still furthermore, the fourth embodiment includes the organic electroluminescent element of which light emitting layer is constituted of polyfulorene and a derivative thereof expressed by (Ka 1) described in the first embodiment.

The fourth embodiment includes the organic electroluminescent element of which light emitting layer is constituted of a material having a phenylene vinylene group.

Furthermore, the fourth embodiment includes the organic electroluminescent element of which light emitting layer is constituted of polyfulorene and a derivative thereof expressed by (Ka 2) described in the first embodiment.

Furthermore, the fourth embodiment includes the organic electroluminescent element of which light emitting layer is constituted of at least one kind of polymer having a dendrimer structure.

Still furthermore, the fourth embodiment includes the organic electroluminescent element of which light emitting layer is constituted of a dendrimer polymer or a dendrimer low molecular structure having a light emitting structural unit at a center.

The fourth embodiment includes the method of producing an organic electroluminescent element, in which the forming a transition metal oxide layer is forming by use of a dry process at least one layer of molybdenum oxide, vanadium oxide and tungsten oxide.

According to an organic electroluminescent device of the invention, an organic electroluminescent element that can reduce the fluctuation between pixels and is high in the accuracy and reliability can be provided.

That is, with a thin film of a transition metal oxide such as molybdenum oxide, a hole injection layer expanding over a plurality of elements is integrally formed to protect a base layer; accordingly, a device that does not cause the deterioration of the light emitting layer, is free from the crosstalk, has long lifetime and is high in the performance even in a top emission structure can be provided.

An organic electroluminescent device of the invention can be stably operated over a wide brightness range and is excellent in the life characteristics; accordingly, the organic electroluminescent device is useful in a wide range of applications including a flat-panel display, a display light emitting device or a light source.

This application is based upon and claims the benefit of priority of Japanese Patent Application No 2006-167580 filed on 06/06/16, Japanese Patent Application No 2006-209823 filed on Jun. 8, 2001, Japanese Patent Application No. 2006-210895 filed on Jun. 8, 2002, Japanese Patent Application No 2006-213495 filed on Jun. 8, 2004, the contents of which are incorporated herein by reference in its entirety.

What is claimed is:

1. An organic electroluminescent device with a plurality of light emitting portions on a substrate, wherein the light emitting portion comprises:
a pair of electrodes;
a light emitting layer interposed between the electrodes; and
a transition metal oxide layer disposed between at least one of the electrodes and the light emitting layer,
wherein the transition metal oxide layer is formed over the plurality of light emitting portions.

2. The organic electroluminescent device of claim 1, wherein the transition metal oxide layer is formed so as to cover on the electrodes formed on the substrate.

3. The organic electroluminescent device of claim 1, wherein the transition metal oxide layer is formed between an electrode on a side that faces the substrate with respect to the light emitting layer and the light emitting layer.

4. The organic electroluminescent device of claim 1, wherein the transition metal oxide layer includes:
a first transition metal oxide layer formed so as to cover on the electrode formed on the substrate; and
a second transition metal oxide layer further formed thereon integrally with a top layer of the light emitting layer.

5. The organic electroluminescent device of claim 1, wherein an effective area of a first electrode formed on the substrate of the pair of electrodes is defined by a pixel restricting layer formed from an insulating film; and
the transition metal oxide layer is integrally formed so as to cover on the pixel restricting layer.

6. The organic electroluminescent device of claim 5, wherein in a recess of a surface of the transition metal oxide layer a light emitting layer is filled.

7. The organic electroluminescent device of claim 5, wherein in a recess of a surface of the transition metal oxide layer a plurality of kinds of light emitting layers is filled so as to sequentially arrange.

8. The organic electroluminescent device of claim 1, wherein the pair of electrodes has a matrix wiring structure and an intersection constitutes a light emitting portion.

9. The organic electroluminescent device of claim 1, wherein the light emitting layer is interposed between an anode constituted of a reflective material on the substrate and a cathode constituted of a translucent material and a transition metal oxide layer is disposed between the light emitting layer and the anode.

10. The organic electroluminescent device of claim 1 wherein the transition metal oxide layer includes any one of molybdenum oxide, vanadium oxide and tungsten oxide.

11. A method of producing an organic electroluminescent device having a plurality of light emitting portions, comprising:
forming a first electrode on a substrate;
forming, as a top layer of the first electrode, a light emitting layer constituted of an organic semiconductor;
forming, as a top layer of the light emitting layer, a second electrode; and
forming a transition metal oxide layer between at least one electrode of the first and second electrodes and the light emitting layer so as to be integrated over a plurality of light emitting portions.

12. The method of producing an organic electroluminescent device of claim 11, wherein the forming a transition metal oxide layer is forming so as to cover on an electrode formed on the substrate.

13. The method of producing an organic electroluminescent device of claim 11, wherein the forming a transition metal oxide layer is forming integrally with a top layer of the light emitting layer.

14. The method of producing an organic electroluminescent device of claim 11, wherein the forming a transition metal oxide layer includes:
forming a first transition metal oxide layer so as to cover on an electrode formed on the substrate; and
forming a second transition metal oxide layer integrally with a top layer of the light emitting layer, wherein
the first and second transition metal oxide layers are formed so as to be disposed on both sides of the light emitting layer.

15. The method of producing an organic electroluminescent device of claim 11, further comprising:
forming a pixel restricting layer so that an effective area of a first electrode formed on a substrate of the pair of electrodes is defined by the pixel restricting layer constituted of an insulating film, wherein the transition metal oxide layer is integrally formed so as to cover on the pixel restricting layer.

16. The method of producing an organic electroluminescent device of claim 15, wherein the forming a light emitting layer includes filling a light emitting layer in a recess of a surface of the transition metal oxide layer by means of an inkjet method.

17. The method of producing an organic electroluminescent device of claim 15, wherein the filling is filling a plurality of kinds of light emitting layers in a recess on a surface of the transition metal oxide layer so as to sequentially arrange.

18. The method of producing an organic electroluminescent device of claim 11, wherein the forming the first and second electrodes includes patterning the respective electrodes in stripe so that an intersection of a matrix wiring forms a light emitting portion.

19. The method of producing an organic electroluminescent device of claim 11, further comprising:
forming a anode with a reflective material on a substrate;
forming a transition metal oxide layer between the anode and the light emitting layer; and
forming a cathode constituted of a translucent material.

20. The method of producing an organic electroluminescent device of claim 11, wherein the forming a transition metal oxide layer is forming any one of a tungsten oxide layer, a molybdenum oxide layer and a vanadium oxide layer by a dry process.
